(19) United States
(12) Patent Application Publication
(10) Pub. No.: US 2026/0371511 A1
(43) Pub. Date: Nov. 19, 2026

(54) PROTECTIVE FILM, ELECTRONIC DEVICE INCLUDING THE SAME AND METHOD FOR MANUFACTURING THE PROTECTIVE FILM

(71) Applicant: Samsung Display Co., LTD., Yongin-si (KR)

(72) Inventors: Kyung Man KIM, Yongin-si (KR); Cheol Geun AN, Yongin-si (KR); Eui Yun JANG, Yongin-si (KR)

(21) Appl. No.: 19/577,513

(22) Filed: Mar. 25, 2026

(30) Foreign Application Priority Data
May 19, 2025 (KR) 10-2025-0064667
Jul. 31, 2025 (KR) 10-2025-0104626

(51) Int. Cl. H05K 5/03

(52) U.S. Cl. CPC H05K 5/03

(57) ABSTRACT

A protective film includes: a first adhesive layer including a main region and a pad region spaced apart from each other with a bending region interposed between the main region and the pad region; a first structural layer disposed on the main region of the first adhesive layer and including glass or metal; a first resin layer disposed on the main region of the first adhesive layer; a second resin layer disposed on the pad region of the first adhesive layer; a first bonding layer disposed on the first resin layer; a second bonding layer disposed on the second resin layer; and a second adhesive layer disposed on the first bonding layer and the second bonding layer and overlapping the main region, the pad region, and the bending region; wherein the first resin layer and the second resin layer include a same material as each other.

This application claims priority to Korean Patent Application No. 10-2025-0064667, filed on May 19, 2025, and Korean Patent Application No. 10-2025-0104626, filed on Jul. 31, 2025, and all the benefits accruing therefrom under 35 U.S.C. § 119, the contents of which in their entireties are herein incorporated by reference.

### BACKGROUND

### 1. Field

The present disclosure relates to a protective film, an electronic device including the protective film and a method for manufacturing the protective film.

### 2. Description of the Related Art

With the advance of information-oriented society, more and more demands are placed on display devices for displaying images in various ways. The display device may be a flat panel display device such as a liquid crystal display, a field emission display and a light emitting display. Examples of the light emitting display device may include an organic light emitting display device including organic light emitting elements, an inorganic light emitting display device including inorganic light emitting elements such as inorganic semiconductors, and a micro light emitting display device including micro light emitting elements.

Recently, a flexible display device, which is manufactured to be capable of displaying an image even when bent or folded like paper, has been gaining attention as a next-generation display device. The flexible display device may be classified into an unbreakable type having high durability, a bendable type which can be bent without breaking, a rollable type which can be rolled, and a foldable type which can be folded, by utilizing a flexible thin film transistor substrate. Such a flexible display device may have various desirable characteristics in space utilization, interior, and design, and may be applicable to various fields.

### SUMMARY

Since a flexible display device such as a foldable display device is desired to be capable of being folded and unfolded, elements thereof, e.g., a display panel, a back plate, and a cover window, may be all in the form of very thin films. Although a structure including ultra-thin glass (UTG) has been proposed to improve the impact resistance of the back plate and the cover window, this has problems such as difficulties in the manufacturing process and low product reliability.

Embodiments of the present disclosure provide a protective film having improved reliability by minimizing tolerances through a reduced number of lamination and punching processes during the manufacturing process.

However, embodiments of the present disclosure are not restricted to the one set forth herein. The above and other embodiments of the present disclosure will become more apparent to one of ordinary skill in the art to which the present disclosure pertains by referencing the detailed description of the present disclosure given below.

According to embodiments of the present disclosure, a protective film includes: a first adhesive layer including a main region and a pad region spaced apart from each other with a bending region interposed between the main region and the pad region; a first structural layer disposed on the main region of the first adhesive layer and including glass or metal; a first resin layer disposed on the main region of the first adhesive layer; a second resin layer disposed on the pad region of the first adhesive layer; a first bonding layer disposed on the first resin layer; a second bonding layer disposed on the second resin layer; and a second adhesive layer disposed on the first bonding layer and the second bonding layer and overlapping the main region, the pad region, and the bending region, where the first resin layer and the second resin layer include a same material as each other.

In an embodiment, a difference between a thickness of the first resin layer and a thickness of the second resin layer may be equal to or less than about 1 micrometer (μm).

In an embodiment, a difference between a distance from the first adhesive layer to the second adhesive layer in the main region and a distance from the first adhesive layer to the second adhesive layer in the pad region may be equal to or less than about 1 μm.

In an embodiment, the glass includes ultra thin glass (UTG) or hybrid thin glass.

In an embodiment, the first structural layer may be in contact with the first adhesive layer.

In an embodiment, the first structural layer may be in contact with the first bonding layer.

In an embodiment, a modulus of the first resin layer may be less than a modulus of the second resin layer.

In an embodiment, the protective film further includes a second structural layer disposed on the pad region of the first adhesive layer and including a polymer.

In an embodiment, a modulus of the second structural layer may be equal to or greater than about 2.0 gigapascals (GPa).

In an embodiment, the second structural layer may be in contact with the first adhesive layer.

In an embodiment, the second structural layer may be in contact with the first bonding layer.

In an embodiment, the first structural layer may have a pattern.

According to embodiments of the present disclosure, there may be provided a method for manufacturing a protective film, including: forming a plurality of first structural layers to be spaced apart from each other on a first adhesive film, where the plurality of first structural layers includes glass or metal; forming a resin layer on the first adhesive film on which the plurality of first structural layers are formed; forming a second adhesive film on the resin layer; curing the resin layer; forming a bonding layer on the resin layer exposed by removing the first adhesive film or the second adhesive film; forming a third adhesive film on the bonding layer; manufacturing a protective film by removing a portion of each of the resin layer, the bonding layer, and the third adhesive film to form a bending region; and cutting the protective film into cell units including a main region and a pad region spaced apart from each other with the bending region interposed between the main region and the pad region, where the first structural layer overlaps the main region.

In an embodiment, the method may further include removing the third adhesive film and forming a fourth adhesive film on the bonding layer.

In an embodiment, the forming the resin layer and the forming the second adhesive film may be performed simultaneously using at least one method selected from gap coating, roll-to-roll, doctor blade, and offset coating.

In an embodiment, the forming the bonding layer and the forming the third adhesive film are performed simultaneously using at least one method selected from gap coating, roll-to-roll, doctor blade, and offset coating.

In an embodiment, in the curing the resin layer, ultraviolet light may be radiated to the resin layer, and an intensity and/or exposure time of the ultraviolet light radiated onto the resin layer overlapping the pad region is greater than an intensity and/or exposure time of the ultraviolet light radiated onto the resin layer overlapping the main region.

In an embodiment, the method may further include forming a second structural layer on the pad region of the first adhesive film, where the second structural layer may include a polymer.

In an embodiment, the method may further include forming a third structural layer on the first adhesive film in a region symmetrical to the second structural layer with respect to the first structural layer formed on the first adhesive film, where the third structural layer may include a polymer.

According to embodiments of the present disclosure, an electronic device includes: a display device which displays an image; a processor which transmits an image data signal to the display device, where the display device includes: a display panel; and a protective film disposed on the display panel, where the protective film includes: a first adhesive layer including a main region and a pad region spaced apart from each other with a bending region interposed between the main region and the pad region; a first structural layer disposed on the main region of the first adhesive layer and including glass or metal; a first resin layer disposed on the main region of the first adhesive layer; a second resin layer disposed on the pad region of the first adhesive layer; a first bonding layer disposed on the first resin layer and overlapping the main region under the display panel; and a second bonding layer disposed on the second resin layer and overlapping the pad region under the display panel, wherein the first resin layer and the second resin layer include a same material as each other.

In the display device according to embodiments, by simultaneously forming a first resin layer and a second resin layer on a first adhesive layer, it is possible to provide a protective film in which a step difference is minimized between the first resin layer including a first structural layer including glass or metal and the second resin layer.

In such embodiments, the process may be simplified to one punching process and one lamination step, thereby reducing the process cost. Furthermore, by reducing the number of lamination processes to minimize tolerances that may occur in the protective film, a protective film with improved reliability may be provided.

It should be noted that effects of the present disclosure are not limited to those described above and other effects of the present disclosure will be apparent to those skilled in the art from the following descriptions.

### BRIEF DESCRIPTION OF THE DRAWINGS

The above and other features of embodiments of the present disclosure will become more apparent by describing in detail embodiments thereof with reference to the attached drawings, in which:

FIG. 1 is a perspective view of a display device according to an embodiment;

FIG. 2 is a side view of a display device according to an embodiment;

FIG. 3 is a cross-sectional view illustrating a display panel according to an embodiment;

FIG. 4 is a plan view of a protective film according to an embodiment;

FIG. 5 is a cross-sectional view of a protective film according to an embodiment taken along line A-A′ of FIG. 4;

FIG. 6 is a cross-sectional view of a protective film according to another embodiment taken along line A-A′ of FIG. 4;

FIG. 7 is a cross-sectional view of a protective film according to another embodiment taken along line A-A′ of FIG. 4;

FIG. 8 is a cross-sectional view of a protective film according to another embodiment taken along line A-A′ of FIG. 4;

FIG. 9 is a cross-sectional view of a protective film according to another embodiment taken along line A-A′ of FIG. 4;

FIG. 10 is a cross-sectional view of a protective film according to another embodiment taken along line A-A′ of FIG. 4;

FIG. 11 is a cross-sectional view of a protective film according to another embodiment taken along line A-A′ of FIG. 4;

FIG. 12 is a cross-sectional view of a protective film according to another embodiment taken along line A-A′ of FIG. 4;

FIG. 13 is a plan view of a protective film according to an embodiment;

FIG. 14 is a plan view of a protective film according to an embodiment;

FIG. 15 is a flowchart showing a method for manufacturing a protective film according to an embodiment;

FIG. 16 is a plan view, illustrating the first adhesive film and the first structural layer of FIG. 5 in process S100 of FIG. 15 according to an embodiment;

FIG. 17 is a cross-sectional view of the first adhesive film and the first structural layer taken along line B-B′ of FIG. 16;

FIG. 18 is a plan view, illustrating the first adhesive film and the first structural layer of FIG. 5 in process S100 of FIG. 15 according to another embodiment;

FIG. 19 is a cross-sectional view of the first adhesive film and the first structural layer taken along line C-C′ of FIG. 18;

FIG. 20 is a plan view of an embodiment, illustrating a first adhesive film, a first structural layer, and a second structural layer;

FIG. 21 is a plan view of an embodiment, illustrating a first adhesive film, a first structural layer, and a second structural layer;

FIG. 22 is a plan view of an embodiment, illustrating a first adhesive film, a first structural layer, and a second structural layer;

FIG. 23 is a plan view of an embodiment, illustrating a second adhesive film and a second structural layer;

FIG. 24 is a plan view of an embodiment, illustrating a first adhesive film, a first structural layer, and a second structural layer;

FIG. 25 is a plan view of an embodiment, illustrating a first adhesive film, a first structural layer, and a second structural layer;

FIG. 26 is a cross-sectional view of an embodiment, illustrating the first adhesive film, the first structural layer, and the resin layer in process S200 of FIG. 15;

FIG. 27 is a cross-sectional view of an embodiment, illustrating the first adhesive film, the first structural layer, the resin layer, and the second adhesive film in processes S200 and S300 of FIG. 15;

FIG. 28 is a diagram showing an embodiment of a manufacturing apparatus for manufacturing the first adhesive film, the first structural layer, the resin layer, and the second adhesive film in processes S200 and S300 of FIG. 15;

FIG. 29 is a diagram illustrating the photocuring of the first adhesive film, the first structural layer, the resin layer, and the second adhesive film in process S400 of FIG. 15;

FIG. 30 is a cross-sectional view of an embodiment, illustrating the first adhesive film, the first structural layer, the resin layer, and the bonding layer in process S500 of FIG. 15;

FIG. 31 is a cross-sectional view of an embodiment, illustrating the first adhesive film, the first structural layer, the resin layer, the bonding layer, and the third adhesive film in process S600 of FIG. 15;

FIG. 32 is a diagram illustrating an embodiment of a manufacturing apparatus for manufacturing the first adhesive film, the first structural layer, the resin layer, the bonding layer, and the third adhesive film in processes S500 and S600 of FIG. 15;

FIG. 33 is a diagram illustrating an embodiment of a manufacturing apparatus for manufacturing the first adhesive film, the first structural layer, the resin layer, the bonding layer, and the third adhesive film in processes S500 and S600 of FIG. 15;

FIG. 34 is a cross-sectional view of an embodiment, illustrating the first adhesive film, the first structural layer, the resin layer, the bonding layer, and the third adhesive film in process S700 of FIG. 15;

FIG. 35 is a cross-sectional view of an embodiment, illustrating the first adhesive film, the first structural layer, the resin layer, the bonding layer, and the third adhesive film in process S800 of FIG. 15;

FIG. 36 is a cross-sectional view of one embodiment, illustrating the protective film manufactured after being cut into cell units in step S800 of FIG. 15;

FIG. 37 is a cross-sectional view of an embodiment, illustrating the protective film manufactured after being cut into cell units;

FIG. 38 is a block diagram of an electronic device according to an embodiment; and

FIG. 39 is schematic views of electronic devices according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below. “About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

The individual features of the various embodiments of the present invention may be partially or fully combined or combined with each other, and various technically diverse interconnections and operations may be possible. Each embodiment may be implemented independently of the other or may be implemented together in a related manner.

Hereinafter, embodiments will be described in detail with reference to the accompanying drawings.

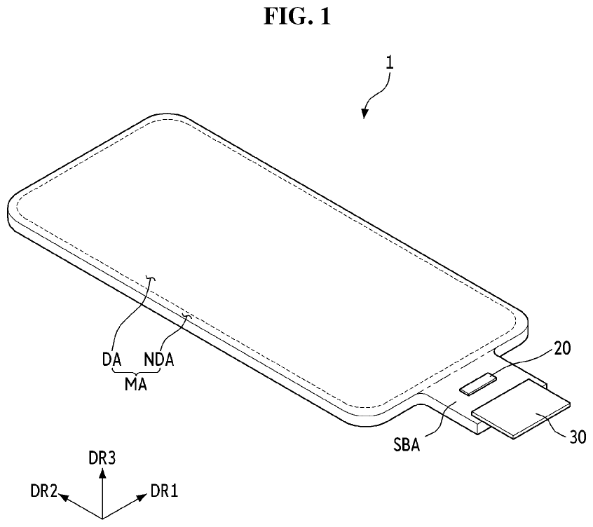

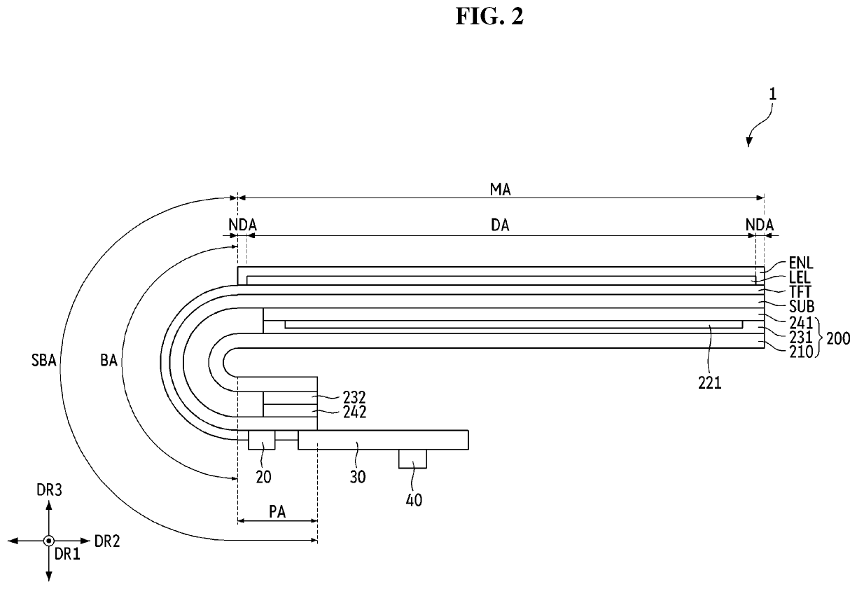

FIG. 1 is a perspective view of a display device according to an embodiment. FIG. 2 is a side view of a display device according to an embodiment.

Referring to FIG. 1, an embodiment of a display device 1 is a device for displaying a moving image or a still image. The display device 1 may be used as a display screen of various devices, such as a television (TV), a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 1 according to an embodiment may be a light emitting display device such as an organic light emitting display using an organic light emitting diode, a quantum dot light emitting display including a quantum dot light emitting layer, an inorganic light emitting display including an inorganic semiconductor, and a micro or nano light emitting display using a micro or nano light emitting diode (LED). In the following description, for convenience of description, embodiments where the display device 1 is an organic light emitting display device will be mainly described, but the embodiment of the present disclosure is not limited thereto.

In an embodiment, the display device 1 includes a display panel 100, a display driving circuit 20, a circuit board 30, and a protective film 200 (see FIG. 2).

The display panel 100 may, in a plan view (or when viewed in a thickness direction of the display panel 100), be formed in a rectangular shape having short sides in a first direction DR1 and long sides in a second direction DR2 crossing the first direction DR1. Further, the display panel 100 may have a thickness in a third direction DR3 that intersects the first direction DR1 and the second direction DR2. The corner where the short side in the first direction DR1 and the long side in the second direction DR2 meet may be rounded to have a selected curvature or may be right-angled. The planar shape of the display panel 100 is not limited to the rectangular shape, and may be formed in another polygonal shape, a circular shape or an elliptical shape. The display panel 100 may be formed to be flat, but is not limited thereto. In an embodiment, for example, the display panel 100 may include a curved portion formed at left and right ends and having a constant curvature or a varying curvature. In an embodiment, the display panel 100 may be formed flexibly so that the display panel 100 can be curved, bent, folded, or rolled.

The display panel 100 may include a main region MA and a sub-region SBA.

The main region MA may include a display area DA for displaying an image and a non-display area NDA that is a peripheral area of the display area DA. The display area DA may occupy most of the main region MA. The display area DA may be located at the center of the main region MA. The non-display area NDA may be located adjacent to the display area DA. The non-display area NDA may be an area outside the display area DA. The non-display area NDA may be located to surround the display area DA. The non-display area NDA may be an edge area of the display panel 100. A plurality of pixels may be located in the display area DA to display an image. The display area DA may be an area including the pixels to display an image. In an embodiment, for example, the display area DA may include pixel areas where the pixels are arranged.

The sub-region SBA may extend in the first direction DR1 from one side of the main region MA. The length of the sub-region SBA in the first direction DR1 may be less than the length of the main region MA in the first direction DR1. The length of the sub-region SBA in the second direction DR2 may be substantially equal to or less than the length of the main region MA in the second direction DR2. The sub-region SBA may be foldable to be located under the display panel 100. In a state where the sub-region SBA is folded, the sub-region SBA may overlap the main region MA in the third direction DR3.

The display panel 100 may further include a bending region BA and a pad region PA. In an embodiment, the bending region BA and the pad region PA may be included in the sub-region SBA of the display panel 100.

The bending region BA may extend in the first direction DR1 from one side of the main region MA. The length of the bending region BA in the first direction DR1 may be less than the length of the sub-region SBA in the first direction DR1. The length of the bending region BA in the second direction DR2 may be substantially equal to or less than the length of the main region MA in the second direction DR2. The bending region BA may be foldable to be located under the display panel 100. The main region MA and the pad region PA may be spaced apart from each other with the bending region BA interposed between the main region MA and the pad region PA.

The pad region PA may extend in the first direction DR1 from one side of the bending region BA. The pad region PA may be the remaining region of the sub-region SBA excluding the bending region BA. The length of the pad region PA in the first direction DR1 may be less than the length of the sub-region SBA in the first direction DR1. The pad region PA may be located below the display panel 100, and in this state where the pad region PA is located below the display panel 100, the pad region PA may overlap the main region MA in the third direction DR3.

The display driving circuit 20 may generate signals and voltages for driving the display panel 100. The display driving circuit 20 may be formed as an integrated circuit (IC) and attached to the sub-region SBA of the display panel 100 by a chip on glass (COG) method, a chip on plastic (COP) method, or an ultrasonic bonding method. Alternatively, the display driving circuit 20 may be attached onto the circuit board 30 by a chip on film (COF) method.

The circuit board 30 may be attached to one end of the sub-region SBA of the display panel 100. Thus, the circuit board 30 may be electrically connected to the display panel 100 and the display driving circuit 25. The display panel 100 and the display driving circuit 20 may receive digital video data, timing signals, and driving voltages through the circuit board 30. The circuit board 30 may be a flexible printed circuit board, a printed circuit board, or a flexible film such as a chip on film.

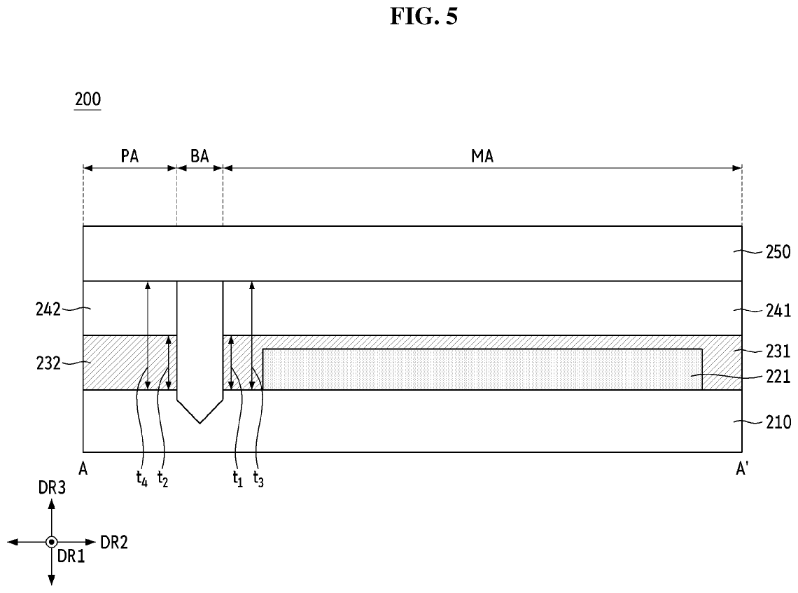

The protective film 200 may be located below the display panel 100. The protective film 200 may be partially etched to secure the bending region BA. A first adhesive layer 210 of the protective film 200 may be located to overlap the entirety of the main region MA, the pad region PA, and the bending region BA, and a first structural layer 221, a first resin layer 231 and a first bonding layer 241 of the protective film 200 may be located to overlap the main region MA, and a second resin layer 232 and a second bonding layer 242 of the protective film 200 may be located to overlap the pad region PA. A second adhesive layer 250 of the protective film 200 (see FIG. 5) may be removed before being attached to the bottom of the display panel 100.

A light blocking layer (not shown) for absorbing light incident from the outside, a buffer layer (not shown) for absorbing impact from the outside, and a heat dissipation layer (not shown) for efficiently dissipating heat from the display panel 100 may be further located under the display panel 100.

The light blocking layer may block the transmission of light, thereby preventing the components arranged below the light blocking layer from being viewed from above the display panel 100. The light blocking layer may include a light absorbing material such as a black pigment, black dyes or the like.

The buffer layer may absorb an external impact to effectively prevent the display panel 100 from being damaged. The buffer layer may be formed as (or defined by) a single layer or multiple layers. In an embodiment, for example, the buffer layer may include a polymer resin such as polyurethane (PU), polycarbonate (PC), polypropylene (PP), or polyethylene (PE) or may include an elastic material such as sponge obtained by foam-molding rubber, a urethane-based material, or an acrylic-based material.

The heat dissipation layer may include a first heat dissipation layer including graphite, carbon nanotubes or the like, and a second heat dissipation layer including a metal thin film including, for example, copper, nickel, ferrite, or silver which can shield electromagnetic waves and has high thermal conductivity.

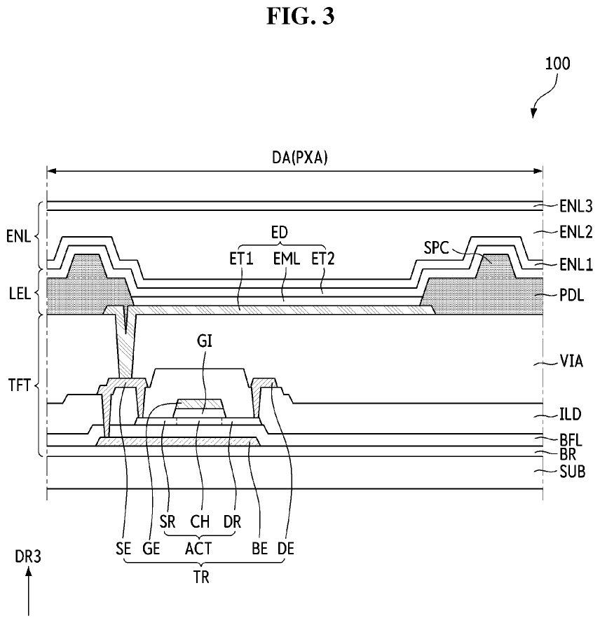

FIG. 3 is a cross-sectional view illustrating a display panel according to an embodiment. For example, FIG. 3 shows a part of the display area DA of the display panel 100. FIG. 3 illustrates a light emitting display panel including a light emitting element ED (for example, an organic light emitting diode) as an example of the display panel 100 to which embodiments are applied.

Referring to FIG. 3, an embodiment of the display panel 100 may include a substrate SUB (or a base layer), a thin film transistor layer TFT, a light emitting element layer LEL, and an encapsulation layer ENL. The thin film transistor layer TFT, the light emitting element layer LEL, and the encapsulation layer ENL may be located to overlap each other on the substrate SUB. In an embodiment, for example, with respect to the display area DA, the thin film transistor layer TFT, the light emitting element layer LEL, and the encapsulation layer ENL may be sequentially located on the substrate SUB along the third direction DR3.

In an embodiment, the display panel 100 may further include additional elements located above and/or under the encapsulation layer ENL. In an embodiment, for example, the display panel 100 may further include at least one selected from a sensor layer (for example, a touch sensor layer), an optical layer (for example, a color filter layer and/or a wavelength conversion layer), or a passivation layer (for example, a passivation film, an insulating layer, an upper substrate, and/or a window). Each of the sensor layer, the optical layer, and/or the passivation layer may be located above the encapsulation layer ENL or may be located between the light emitting element layer LEL and the encapsulation layer ENL.

The substrate SUB, as a base member for forming the display panel 100, may be rigid or flexible. In an embodiment, the substrate SUB may be a substrate including an insulating material such as glass or the like and having rigid characteristics, and may not be bent. Alternatively, the substrate SUB may be a flexible substrate that includes polyimide or another insulating material and may be transformed to be bent, folded, or rolled, and may or may not be bent.

The thin film transistor layer TFT (e.g., a backplane circuit layer or a thin film transistor layer) may be located on the substrate SUB. The thin film transistor layer TFT may include circuit elements of the pixels including pixel transistors and capacitors, and wires (e.g., signal lines and power lines).

In an embodiment, transistors TR may be simultaneously formed using a same material, and may have substantially the same or similar cross-sectional structures as each other. In an embodiment, for example, the transistors TR of the pixels may be simultaneously formed using a same oxide semiconductor, and may have substantially the same or similar cross-sectional structures as each other. In an embodiment, for example, active layers ACT of the transistors TR may be located in a same layer (e.g., directly on a buffer layer BFL) in the thin film transistor layer TFT, and may include a same oxide semiconductor.

The thin film transistor layer TFT may include a plurality of conductive layers and at least one semiconductor layer located on the substrate SUB (or a barrier layer BR). The thin film transistor layer TFT may further include a plurality of insulating layers and/or insulating patterns located on the substrate SUB (or the barrier layer BR).

Patterns included in the conductive layers of the thin film transistor layer TFT may include electrodes constituting the circuit elements of the thin film transistor layer TFT, conductive patterns connected to the circuit elements, and/or wires. The patterns (e.g., electrodes, conductive patterns, and/or wires of each conductive layer) included in each conductive layer of the thin film transistor layer TFT may include at least one conductive material. In an embodiment, for example, the patterns included in each conductive layer of the thin film transistor layer TFT may include at least one selected from copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), or another metal, an alloy thereof, or another conductive material. In an embodiment, patterns included in a same conductive layer may be simultaneously formed using a same conductive material.

The patterns included in the semiconductor layer of the thin film transistor layer TFT may include the active layers ACT of the transistors located in the thin film transistor layer TFT. In an embodiment, the active layers ACT of pixel transistors PXT and circuit transistors may be simultaneously formed using a same semiconductor material (e.g., the same oxide semiconductor). Accordingly, the active layers ACT of the transistors TR and the circuit transistors may be located in a same layer and may include a same semiconductor material as each other.

The insulating layers and/or insulating patterns of the thin film transistor layer TFT may include the barrier layer BR, the buffer layer BFL, a gate insulating layer GI, an interlayer insulating layer ILD, and a planarization layer VIA, which are arranged sequentially on the substrate SUB along the third direction DR3. Each of the insulating layers and/or insulating patterns of the thin film transistor layer TFT may include an inorganic insulating material or an organic insulating material, and may be formed as a single layer or multiple layers.

In an embodiment, at least one selected from the insulating layers of the thin film transistor layer TFT may be located over the entire display area DA. In an embodiment, for example, the barrier layer BR, the buffer layer BFL, the interlayer insulating layer ILD, and the planarization layer VIA may be arranged over the entire display area DA.

When the structure of the thin film transistor layer TFT is described for each layer, the barrier layer BR may first be located on the substrate SUB. The barrier layer BR may include at least one inorganic insulating layer including an inorganic insulating material (e.g., silicon nitride (SiNₓ), silicon oxide (SiOₓ), silicon oxynitride (SiON), titanium oxide (TiOₓ), aluminum oxide (AlₓO_{y}), or another inorganic insulating material). The barrier layer BR may protect the pixels from moisture permeating through the substrate SUB, which is vulnerable to moisture intrusion. The barrier layer BR may be omitted.

A first conductive layer (e.g., a lower conductive layer) including a bottom electrode BE (or a light blocking layer) of at least one transistor may be located on the barrier layer BR (or the substrate SUB). In an embodiment, for example, the bottom electrode BE (or the light blocking layer) of the transistor TR may be located on the barrier layer BR. The bottom electrode BE may be located below the active layer ACT to overlap a channel region CH of the transistor TR. In an embodiment, the bottom electrode BE may also overlap at least a portion of a source region SR and a drain region DR of the transistor TR, but is not limited thereto. Each of the patterns of the first conductive layer including the bottom electrode BE may include at least one conductive material, and may be formed as a single layer or multiple layers.

In an embodiment, the bottom electrode BE may be electrically connected to one electrode (e.g., a source electrode SE) of the transistor TR, and may be used as an electrode for adjusting the characteristics of the transistor TR. In an embodiment, for example, the bottom electrode BE may be electrically connected to the source electrode SE of the transistor TR. When the bottom electrode BE is electrically connected to one electrode of the transistor TR, the bottom electrode BE may also be regarded as a component included in the transistor TR. By arranging the bottom electrode BE below the active layer ACT of the transistor TR, the incidence of external light into the channel region CH and the like of the transistor TR may be blocked. In an embodiment, where the transistors of the thin film transistor layer TFT do not include the bottom electrode BE or the light blocking layer, the first conductive layer may be omitted.

The buffer layer BFL may be located on the barrier layer BR and the bottom electrode BE. The buffer layer BFL may include at least one inorganic insulating layer including an inorganic insulating material (e.g., silicon nitride (SiNₓ), silicon oxide (SiOₓ), silicon oxynitride (SiON), titanium oxide (TiOₓ), aluminum oxide (AlₓO_{y}), or another inorganic insulating material).

The buffer layer BFL may include an insulating material suitable as a barrier material capable of preventing diffusion of oxygen, hydrogen, or the like. In addition to a silicon nitride film including silicon nitride (SiNₓ) and a silicon oxide film including silicon oxide (SiOₓ), the buffer layer BFL may further include another insulating material capable of appropriately blocking oxygen, hydrogen, and/or moisture.

The active layer ACT may include the channel region CH, the source region SR, and the drain region DR. The channel region CH may overlap a gate electrode GE in the third direction DR3 in plan view, and may be located between the source region SR and the drain region DR. The source region SR and the drain region DR may be located on opposite sides of the channel region CH and may be spaced apart from each other with the channel region CH interposed between the source region SR and the drain region DR. The source region SR and the drain region DR (or a portion of each of the source region SR and the drain region DR) may not overlap the gate electrode GE in plan view. The carrier concentration (e.g., an electron concentration) of the source region SR and the drain region DR may be higher than that of the channel region CH.

In an embodiment, the active layers ACT may include an oxide semiconductor. In an embodiment, for example, the active layers ACT may include an oxide semiconductor including at least one selected from indium (In), gallium (Ga), zinc (Zn), tin (Sn), or hafnium (Hf), or other oxide semiconductors. In an embodiment, for example, the active layers ACT may include at least one selected from zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), or indium-tin-gallium-zinc oxide (ITGZO), or another oxide semiconductor.

In embodiments, the active layers ACT of some of the transistors arranged in the thin film transistor layer TFT may be located on the buffer layer BFL.

In an embodiment, at least one transistor TR may be located in each pixel area. Accordingly, the plurality of transistors TR may be located in the display area DA.

The gate insulating layer GI may be located on the active layers ACT. In an embodiment, for example, the gate insulating layer GI may be located on a portion of each active layer ACT including the channel region CH.

The gate insulating layer GI may include at least one inorganic insulating layer including an inorganic insulating material (e.g., silicon nitride (SiNₓ), silicon oxide (SiOₓ), silicon oxynitride (SiON), titanium oxide (TiOₓ), aluminum oxide (AlₓO_{y}), or another inorganic insulating material).

In an embodiment, in each transistor region in which a transistor is located, the gate insulating layer GI may have a shape that is etched to cover a portion of the active layer ACT included in the transistor and to expose another portion of the active layer ACT. In an embodiment, for example, in the region where the transistor TR is located, the gate insulating layer GI may cover the channel region CH of the active layer ACT included in the transistor TR and expose the source region SR and the drain region DR of the active layer ACT.

As the gate insulating layer GI exposes the source regions SR and the drain regions DR, the conductivity of the source regions SR and the drain regions DR may be appropriately and/or easily increased during the manufacturing process of the display panel 100. In an embodiment, for example, due to oxygen-vacancies that are generated in the source regions SR and the drain regions DR during a process of etching the gate insulating layer GI such that at least a portion of each of the source regions SR and the drain regions DR is exposed, the carrier concentration of the source regions SR and the drain regions DR may be increased in a subsequent process (e.g., a process of forming the interlayer insulating layer ILD, and the like) without performing a separate doping process.

However, the embodiments are not limited thereto. In an embodiment, for example, the gate insulating layer GI may entirely cover the active layers ACT of some or all of the transistors included in the thin film transistor layer TFT, except for contact holes or the like for connecting each transistor to other circuit elements or wires.

A second conductive layer (e.g., a gate conductive layer) including the gate electrodes GE may be located on the gate insulating layer GI. In an embodiment, for example, the gate electrode GE of the transistor TR may be located on the gate insulating layer GI covering the channel region CH of the transistor TR. Each of the patterns of the second conductive layer including the gate electrodes GE may include at least one conductive material, and may be formed as a single layer or multiple layers.

The interlayer insulating layer ILD may be located on the buffer layer BFL, the semiconductor layer including the active layers ACT, the gate insulating layer GI, and the second conductive layer including the gate electrodes GE. In an embodiment, for example, the interlayer insulating layer ILD may be located on the buffer layer BFL to cover the semiconductor layer, the gate insulating layer GI, and the patterns of the second conductive layer. The interlayer insulating layer ILD may include at least one inorganic insulating layer including an inorganic insulating material.

A third conductive layer (e.g., a source-drain conductive layer) including the source electrodes SE, the drain electrodes DE, and/or conductive patterns electrically connected to at least some of the transistors TR may be located on the interlayer insulating layer ILD. In an embodiment, for example, the third conductive layer may include the source electrode SE and the drain electrode DE of the transistor TR. Each of the patterns of the third conductive layer may include at least one conductive material, and may be formed as a single layer or multiple layers.

The source electrode SE and the drain electrode DE of the transistor TR may penetrate the interlayer insulating layer ILD to be electrically connected to the source region SR and the drain region DR of the transistor TR, respectively. In an embodiment, the source electrode SE of the transistor TR may penetrate the interlayer insulating layer ILD and the buffer layer BFL to be electrically connected to the bottom electrode BE of the transistor TR.

The planarization layer VIA may be located on the transistor TR. In an embodiment, for example, the planarization layer VIA may be located on the interlayer insulating layer ILD and the third conductive layer. The planarization layer VIA may include at least one organic insulating layer including an organic insulating material (e.g., acryl resin, epoxy resin, phenolic resin, polyamide resin, polyimide resin, or another organic insulating material). The planarization layer VIA may include an inorganic insulating layer or may not include an inorganic insulating layer. The surface (for example, the top surface) of the planarization layer VIA may be substantially flat.

The light emitting element layer LEL may be located on the thin film transistor layer TFT. In an embodiment, for example, the light emitting element layer LEL may be located on the planarization layer VIA, and may be located at least in the display area DA.

The light emitting element layer LEL may include the light emitting element ED for each of the pixels PX. In an embodiment, for example, the light emitting element layer LEL may include a pixel defining film PDL (also referred to as “bank”) that partitions the emission areas of the pixels and the light emitting element ED located in each emission area. In an embodiment, the light emitting element layer LEL may further include a spacer SPC located on a part of the pixel defining film PDL.

Each light emitting element ED may include a first electrode ET1 located in each emission area, and a light emitting layer EML and a second electrode ET2 sequentially located on the first electrode ET1. The first electrode ET1 of the light emitting element ED may penetrate the planarization layer VIA to be electrically connected to at least one transistor TR included in the corresponding pixel PX.

The first electrode ET1 of the light emitting element ED may be a single-layer or multi-layer electrode including at least one conductive material. In an embodiment, the display panel 100 may be a top emission type display panel, and the first electrode ET1 may include a reflective electrode layer including at least one selected from aluminum (Al), molybdenum (Mo), titanium (Ti), copper (Cu), silver (Ag), magnesium (Mg), platinum (Pt), palladium (Pd), gold (Au), nickel (Ni), neodymium (Nd), iridium (Ir), or chromium (Cr), or another reflective conductive material.

The light emitting layer EML of the light emitting element ED may include a high molecular material or a low molecular material. Light emitted from the light emitting layer EML may contribute to image display.

Although FIG. 3 illustrates an embodiment of the display panel 100 in which the light emitting layer EML of the light emitting element ED is individually formed in each pixel area PXA, embodiments are not limited thereto. In an embodiment, for example, the display panel 100 may include the light emitting elements having a tandem structure including the light emitting layer EML formed as a common layer over the entire display area DA.

The second electrode ET2 of the light emitting element ED may include a conductive material. In an embodiment, the second electrode ET2 may be a common layer formed across the entire display area DA to cover the light emitting layer EML and the pixel defining film PDL. In an embodiment, the display panel 100 may be a top emission type display panel, and the second electrode ET2 may include a transparent or translucent electrode layer.

The second electrode ET2 may include a transparent conductive material (TCO) such as indium tin oxide (ITO) or indium zinc oxide (IZO) that can transmit light in the top emission structure, or a semi-transmissive conductive material such as magnesium (Mg), silver (Ag), or an alloy of magnesium (Mg) and silver (Ag). In an embodiment where the second electrode ET2 includes a semi-transmissive conductive material, the light emission efficiency of each of the light emitting elements ED may be increased due to a micro-cavity effect.

The pixel defining film PDL may have an opening corresponding to each emission area and may surround the emission area. In an embodiment, for example, the pixel defining film PDL may be formed to cover an edge portion of the first electrode ET1 of the light emitting element ED and may include an opening exposing the remaining portion of the first electrode ET1. A region where the exposed first electrode ET1 and the light emitting layer EML overlap may be the emission area of each pixel. In an embodiment, the pixel defining film PDL may include an organic material. The pixel defining film may include a light blocking material. The pixel defining film PDL includes a base resin and a colorant. The base resin may include at least one selected from a cardo-based resin, an epoxy-based resin, an acrylate-based resin, a siloxane-based resin, or polyimide. The colorant may be selected from a carbon-based pigment, a metal oxide-based pigment, and an organic pigment. In an embodiment, for example, the carbon-based pigment may be selected from carbon black, carbon nanotubes, titanium black, and vertically aligned nanotube arrays (VANTA) black, but is not limited thereto. In an embodiment, for example, the metal oxide-based pigment may be titanium black (TiNxOy) or a Cu—Mn—Fe-based black pigment, but is not limited thereto. In an embodiment, for example, the organic pigment may be selected from lactam black, perylene black, and aniline black, but is not limited thereto. In another embodiment, for example, the colorant may be a mixture of two or more types of pigments or dyes having different colors. However, the present disclosure is not limited thereto.

The spacer SPC may be located on a part of the pixel defining film PDL. The spacer SPC may include at least one organic insulating layer including an organic insulating material. The spacer SPC may include the same material as the pixel defining film PDL or may include a different material from the pixel defining film PDL. The pixel defining film PDL and the spacer SPC may be sequentially formed through individual mask processes, or may be simultaneously and/or integrally formed using a halftone mask.

The encapsulation layer ENL may be located on the light emitting element layer LEL. The encapsulation layer ENL may cover the light emitting element layer LEL in the display area DA and may extend to the non-display area NDA to be in contact with the thin film transistor layer TFT. The encapsulation layer ENL may block the permeation of oxygen or moisture into the light emitting element layer LEL, and may reduce electrical and/or physical impacts to the thin film transistor layer TFT and the light emitting element layer LEL.

In an embodiment, the encapsulation layer ENL may include a first encapsulation layer ENL1, a second encapsulation layer ENL2, and a third encapsulation layer ENL3 sequentially located on the light emitting element layer LEL. Each of the first encapsulation layer ENL1 and the third encapsulation layer ENL3 may be an inorganic encapsulation layer including an inorganic material. The second encapsulation layer ENL2 may be an organic encapsulation layer including an organic material.

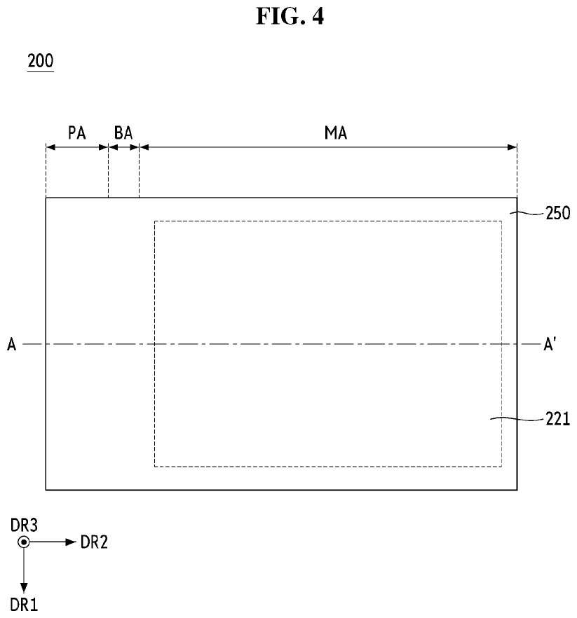

FIG. 4 is a plan view of a protective film according to an embodiment. FIG. 5 is a cross-sectional view of a protective film according to an embodiment taken along line A-A′ of FIG. 4.

Referring to FIGS. 4 and 5, an embodiment of the protective film 200 may include a first adhesive layer 210, a first structural layer 221, a first resin layer 231, a second resin layer 232, a first bonding layer 241, a second bonding layer 242, and a second adhesive layer 250.

The first adhesive layer 210 may be located to overlap (or to correspond to) the entirety of the main region MA, the pad region PA, and the bending region BA. The first adhesive layer 210 may include a transparent adhesive member such as a pressure sensitive adhesive (PSA) film, an optically clear adhesive (OCA) film, an optically clear resin (OCR), or a mixture thereof. However, the type of the adhesive member is not limited thereto.

The first structural layer 221 may be located on a region of the first adhesive layer 210 overlapping the main region MA (hereinafter, will be referred to as the main region MA of the first adhesive layer 210). The first structural layer 221 may include glass or metal. The glass may include hybrid thin glass or ultra thin glass (UTG) having a thickness of about 200 micrometers (μm) or less. Since the thickness of the first structural layer 221 is as thin as about 200 μm or less, stability may be maintained even when the display panel 100 is repeatedly folded and unfolded. The first structural layer 221 may have high hardness to protect the display panel 100. In an embodiment where the first structural layer 221 includes metal, the metal may include a transparent conductive material (TCO) such as ITO or IZO, a semi-transmissive conductive material such as magnesium (Mg), silver (Ag), or an alloy of magnesium (Mg) and silver (Ag), a metal oxide/nitride such as aluminum oxide (Al₂O₃), aluminum oxynitride (AlON), spinel (MgAl₂O₄), silicon oxide (SiO₂), silicon nitride (Si₃N₄), gallium nitride (GaN), or aluminum nitride (AlN), or a metal halide such as zinc sulfide (ZnS) or zinc selenide (ZnSe).

The first resin layer 231 may be located on the main region MA of the first adhesive layer 210. The second resin layer 232 may be located on a region of the first adhesive layer 210 overlapping the pad region PA (hereinafter, will be referred to as the pad region PA of the first adhesive layer 210). The first resin layer 231 and the second resin layer 232 may include a same material as each other. The first resin layer 231 and the second resin layer 232 may be formed simultaneously on the first adhesive layer 210 and then separated from each other with the bending region BA interposed between the first resin layer 231 and the second resin layer 232 by removing portions thereof overlapping or corresponding to the bending region BA.

The difference between a thickness t₁ of the first resin layer 231 and a thickness t₂ of the second resin layer 232 may be about 1 μm or less. Alternatively, the thickness t₁ of the first resin layer 231 and the thickness t₂ of the second resin layer 232 may be substantially the same as each other.

Conventionally, when manufacturing the protective film 200 including the first structural layer 221 in the main region MA, a first film located on the pad region PA and a second film located on the main region MA may be separately formed, that is, formed through separate processes. Accordingly, the thickness of the first film and the thickness of the second film may become different from each other when the first film and the second film are separately formed, such that a step difference between the first film and the second film may occur, and an additional process for compensating for the step difference may be desired to be performed.

In embodiments of the present disclosure, a step difference between the first resin layer 231 and the second resin layer 232 may be minimized by simultaneously forming the first resin layer 231 and the second resin layer 232 on the first adhesive layer 210. In such embodiments, although the first resin layer 231 includes the first structural layer 221, the thickness of the first resin layer 231 may be substantially the same as that of the second resin layer 232.

A modulus (e.g., Young's modulus) of the first resin layer 231 may be less than a modulus (e.g., Young's modulus) of the second resin layer 232. When forming the first resin layer 231 and the second resin layer 232, the intensity and/or exposure time of ultraviolet light may be greater for the resin in the pad region PA than for the resin in the main region MA during curing of the resin. The curing degree of the first resin layer 231 may be lower than that of the second resin layer 232.

The first bonding layer 241 may be located above the main region MA of the first adhesive layer 210. The second bonding layer 242 may be located above the pad region PA of the first adhesive layer 210. The first bonding layer 241 and the second bonding layer 242 may include a same material as each other. The first bonding layer 241 and the second bonding layer 242 may be formed simultaneously above the first adhesive layer 210 and then separated from each other with the bending region BA interposed between the first bonding layer 241 and the second bonding layer 242 by removing portions thereof overlapping or corresponding to the bending region BA.

The second adhesive layer 250 may be located on the first bonding layer 241 and the second bonding layer 242, and may be located to overlap the main region MA, the pad region PA, and the bending region BA. Alternatively, the second adhesive layer 250 may be separated into the second adhesive layer 250 of the main region MA and the second adhesive layer 250 of the pad region PA by removing a portion thereof overlapping or corresponding to the bending region BA. The second adhesive layer 250 may be removed immediately before being attached to the bottom of the display panel 100.

A difference between a distance t₃ from the first adhesive layer 210 to the second adhesive layer 250 in the main region MA and a distance t₄ from the first adhesive layer 210 to the second adhesive layer 250 in the pad region PA may be about 1 μm or less. Alternatively, the difference between the distance t₃ from the first adhesive layer 210 to the second adhesive layer 250 in the main region MA may be substantially the same as the distance t₄ from the first adhesive layer 210 to the second adhesive layer 250 in the pad region PA.

In the protective film 200 according to the embodiment of FIG. 5, the first structural layer 221 may be in contact with the first adhesive layer 210. When the second adhesive layer 250 is attached to the bottom of the display panel 100 and the display device 1 is folded inward, a tensile stress may be applied to the first structural layer 221.

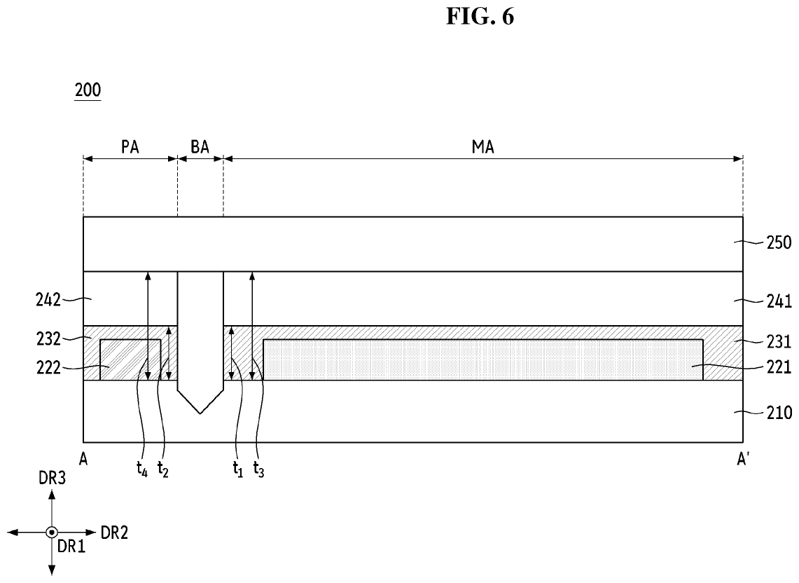

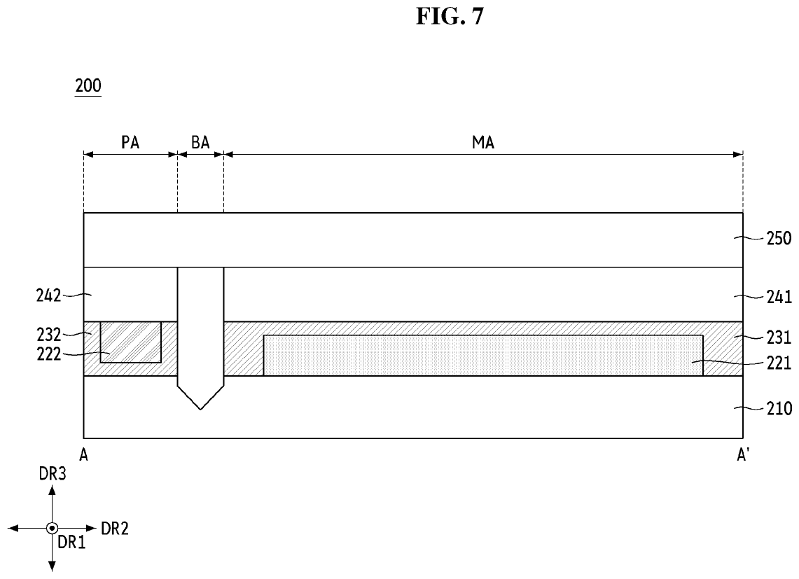

FIG. 6 is a cross-sectional view of a protective film according to another embodiment taken along line A-A′ of FIG. 4. FIG. 7 is a cross-sectional view of a protective film according to another embodiment taken along line A-A′ of FIG. 4.

Embodiments of the protective film 200 of FIGS. 6 and 7 is substantially the same as the protective film 200 according to the embodiment shown in FIG. 5, except that the protective film 200 further includes a second structural layer 222, and thus any repetitive detailed description of the same or like elements as those described above will be omitted below. In an embodiment, as shown in FIG. 6, the second structural layer 222 may be in contact with the first adhesive layer 210. In another embodiment, as shown in FIG. 7, the second structural layer 222 may be in contact with the second bonding layer 242.

The second structural layer 222 may be located on the pad region PA of the first adhesive layer 210. The second structural layer 222 may include a polymer. The second structural layer 222 may include at least one selected from polyethylene terephthalate (PET), polyimide (PI), polytetrafluoroethylene (PTFE), polyether ether ketone (PEEK), polycarbonate (PC), polyphenylene sulfide (PPS), and combinations thereof. However, the type of the polymer material is not limited thereto.

The second structural layer 222 may include a polymer having a modulus (e.g., Young's modulus) of about 2.0 gigapascals (GPa) or more. In such an embodiment where the second structural layer 222 is further included, the hardness of the region of the protective film 200 overlapping the pad region PA may be further improved. Due to the increased hardness of the region of the protective film 200 overlapping the pad region PA, the force for supporting the pad region PA of the display panel 100 may be increased when the protective film 200 is attached to the display panel 100.

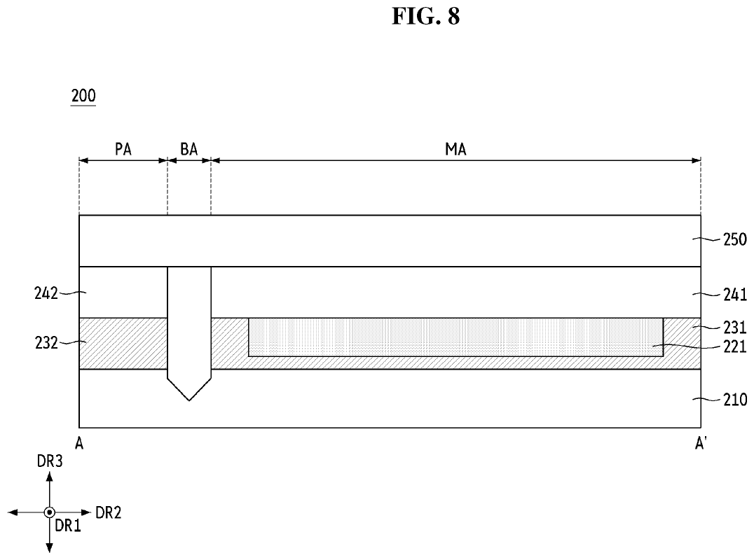

FIG. 8 is a cross-sectional view of a protective film according to another embodiment taken along line A-A′ of FIG. 4.

The protective film 200 of FIG. 8 is substantially the same as the protective film 200 of the embodiment shown in FIG. 5, except that the first structural layer 221 is in contact with the first bonding layer 241, and thus any repetitive detailed description of the same or like elements as those described above will be omitted below.

In the protective film 200 according to the embodiment of FIG. 8, the first structural layer 221 may be in contact with the first bonding layer 241. When the second adhesive layer 250 is attached to the bottom of the display panel 100 and the display device 1 is folded inward, a compressive stress may be applied to the first structural layer 221.

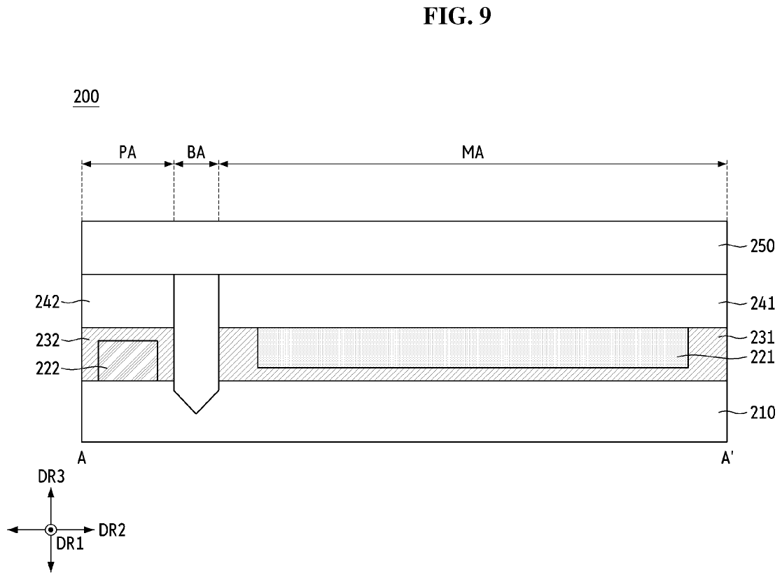

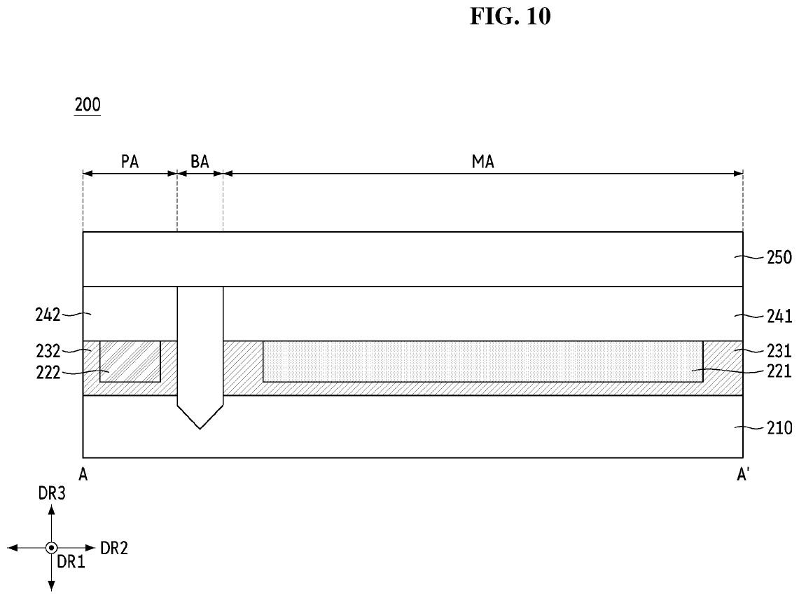

FIG. 9 is a cross-sectional view of a protective film according to another embodiment taken along line A-A′ of FIG. 4. FIG. 10 is a cross-sectional view of a protective film according to another embodiment taken along line A-A′ of FIG. 4.

The protective film 200 of FIGS. 9 and 10 is substantially the same as the protective film 200 of the embodiment shown in FIG. 8, except that the protective film 200 further includes the second structural layer 222, and thus any repetitive detailed description of the same or like elements as those described above will be omitted below. In an embodiment, as shown in FIG. 9, the second structural layer 222 may be in contact with the first adhesive layer 210. In another embodiment, as shown in FIG. 10, the second structural layer 222 may be in contact with the second bonding layer 242.

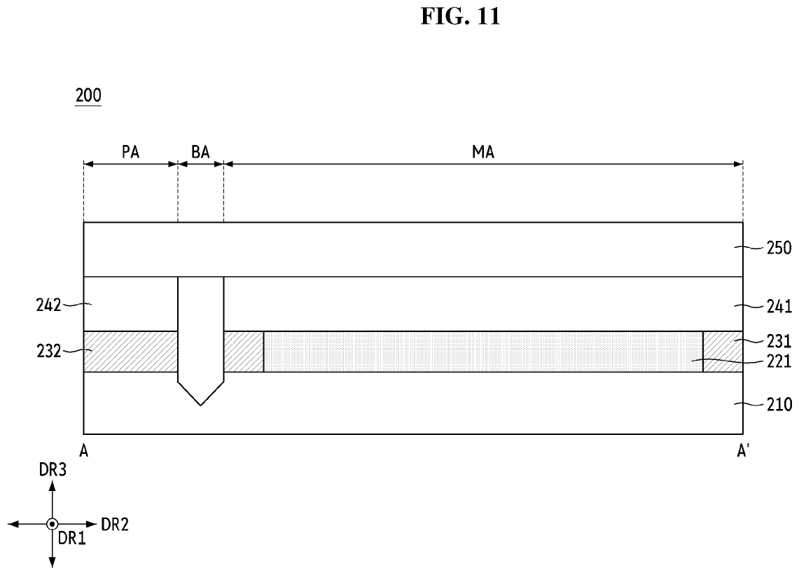

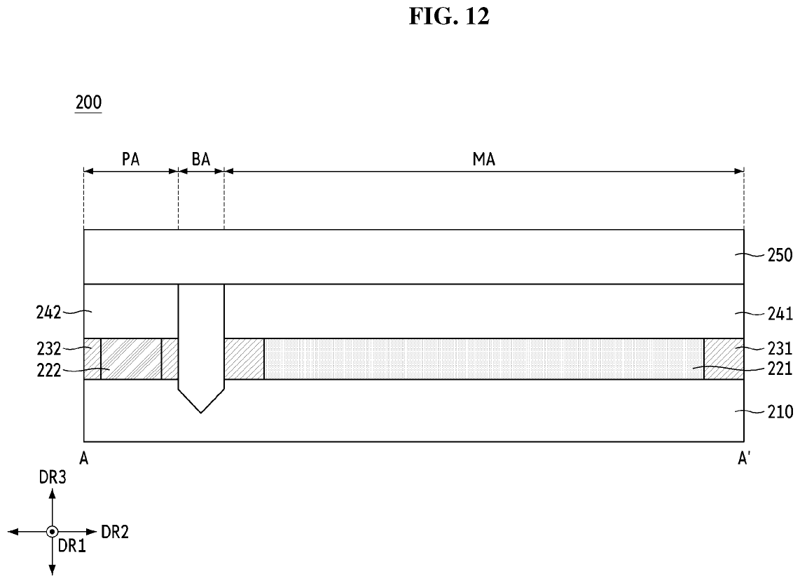

FIG. 11 is a cross-sectional view of a protective film according to another embodiment taken along line A-A′ of FIG. 4. FIG. 12 is a cross-sectional view of a protective film according to another embodiment taken along line A-A′ of FIG. 4.

The protective film 200 of FIG. 11 is substantially the same as the protective film 200 of the embodiment shown in FIG. 5, except that the first structural layer 221 is in contact with the first adhesive layer 210 and the first bonding layer 241, and thus any repetitive detailed description of the same or like elements as those described above will be omitted below. As shown in FIG. 12, the protective film 200 according to the embodiment shown in FIG. 11 may further include the second structural layer 222.

In an embodiment, as shown in FIG. 11, the thickness between the first adhesive layer 210 and the first bonding layer 241 may be substantially the same as the thickness of the first structural layer 221. In an embodiment, as shown in FIG. 12, the thickness between the first adhesive layer 210 and the second bonding layer 242 may be substantially the same as the thickness of the second structural layer 222. In such an embodiment, the thickness of the first structural layer 221 and the thickness of the second structural layer 222 may be substantially the same as each other.

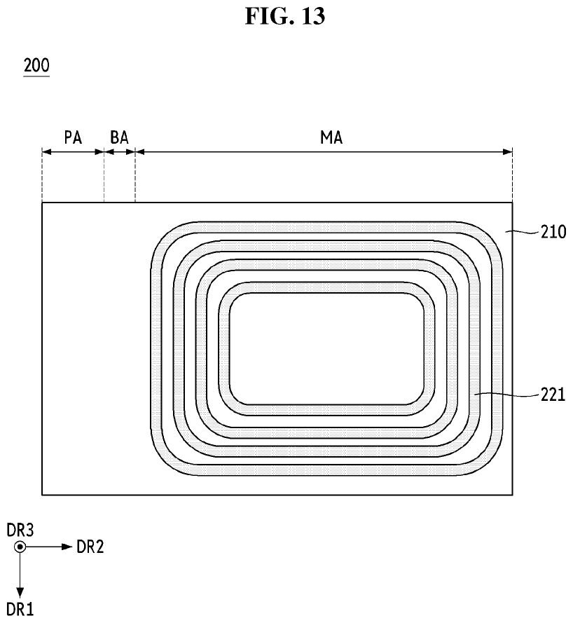

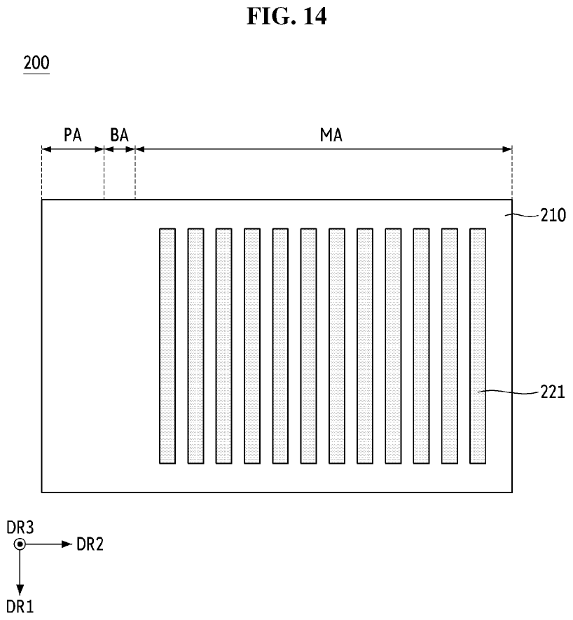

FIG. 13 is a plan view of a protective film according to an embodiment. FIG. 14 is a plan view of a protective film according to an embodiment.

Referring to FIGS. 13 and 14, in an embodiment, the first structural layer 221 may have a pattern. A plurality of first structural layers 221 may form a pattern on the first adhesive layer 210. The number of first structural layers 221 and the shape of the pattern are not limited and may be variously arranged depending on the purpose of use.

Referring to FIG. 13, the first structural layer 221 may be located at a position spaced apart from the edges of the main region MA of the protective film 200. The plurality of first structural layers 221 may be arranged spaced apart from each other on the inner side of the first structural layer 221.

Referring to FIG. 14, the plurality of first structural layers 221 may be arranged in a row in the main region MA of the protective film 200.

FIGS. 13 and 14 illustrate examples of the pattern of the first structural layer 221, and the pattern of the first structural layer 221 is not limited thereto.

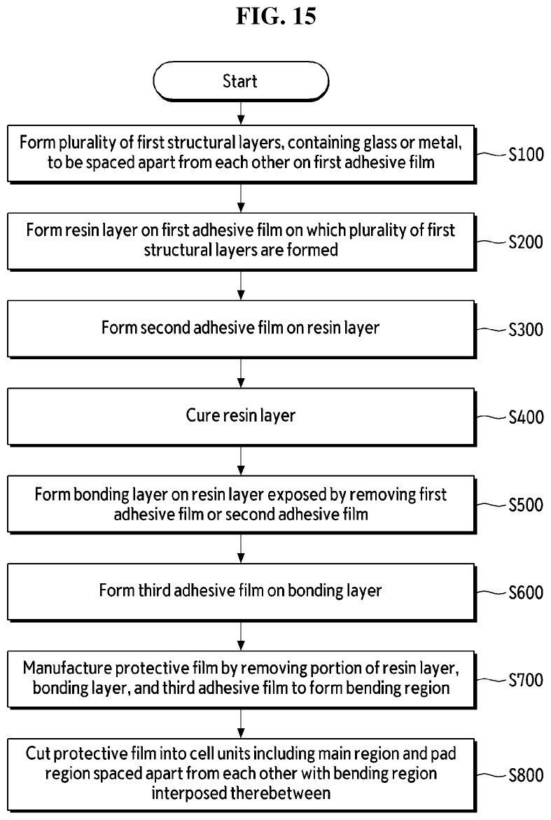

FIG. 15 is a flowchart showing a method for manufacturing a protective film according to an embodiment.

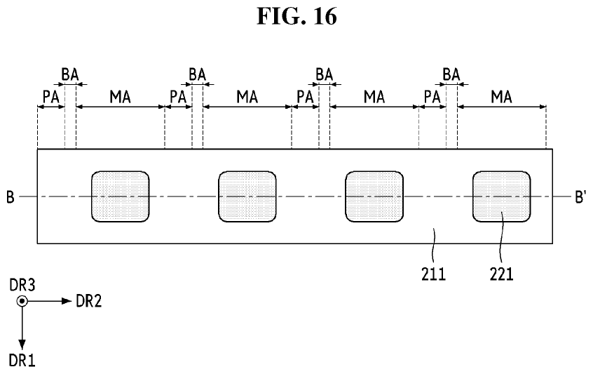

In an embodiment of a method for manufacturing a protective film, the plurality of first structural layers 221 are formed to be spaced apart from each other on a first adhesive film 211 (see FIG. 16) (process S100). The first adhesive film 211 may use the material exemplified above for the first adhesive layer 210. The first structural layer 221 may be formed using the material exemplified above, and a process used for forming the first structural layer 221 is not limited.

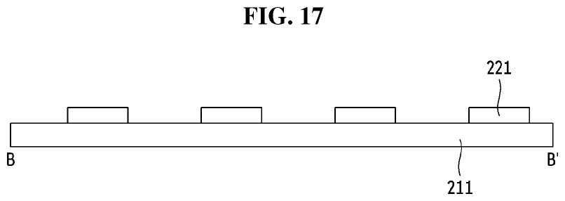

FIG. 16 is a plan view, illustrating the first adhesive film and the first structural layer of FIG. 5 in process S100 of FIG. 15 according to an embodiment. FIG. 17 is a cross-sectional view of the first adhesive film and the first structural layer taken along line B-B′ of FIG. 16.

Referring to FIGS. 16 and 17, in an embodiment of a method for manufacturing a protective film, the first adhesive film 211 may be formed in a rectangular planar shape having short sides in the first direction DR1 and long sides in the second direction DR2 intersecting the first direction DR1. The plurality of the first structural layers 221 may be arranged to be spaced apart from each other in the second direction DR2 of the first adhesive film 211. When the first structural layer 221 is arranged in a region corresponding to the main region MA, another first structural layer 221 may be arranged at a distance therefrom corresponding to the pad region PA and the bending region BA.

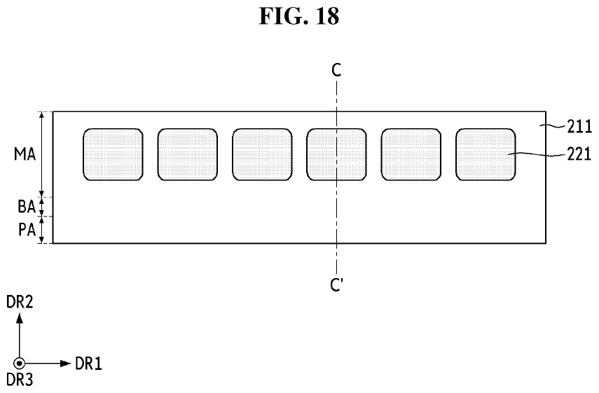

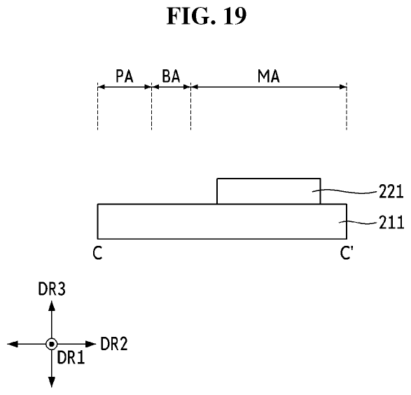

FIG. 18 is a plan view, illustrating the first adhesive film and the first structural layer of FIG. 5 in process S100 of FIG. 15 according to another embodiment. FIG. 19 is a cross-sectional view of the first adhesive film and the first structural layer taken along line C-C′ of FIG. 18.

Referring to FIGS. 18 and 19, in another embodiment of a method for manufacturing a protective film, the first adhesive film 211 may be formed in a rectangular planar shape having short sides in the second direction DR2 and long sides in the first direction DR1 intersecting the second direction DR2. The plurality of first structural layers 221 may be arranged to be spaced apart from each other in the first direction DR1 of the first adhesive film 211. When the first structural layer 221 is arranged in the region corresponding to the main region MA, another first structural layer 221 may be arranged at a regular interval therefrom. The first structural layer 221 may be arranged at a distance corresponding to the pad region PA and the bending region BA in the second direction DR2 of the first adhesive film 211.

In such an embodiment, the second structural layer 222 of FIG. 6 may be formed on the pad region PA of the first adhesive film 211.

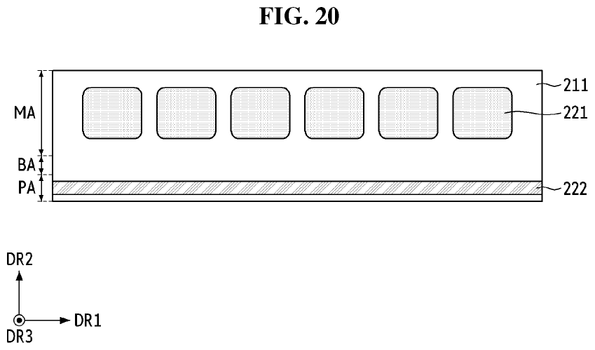

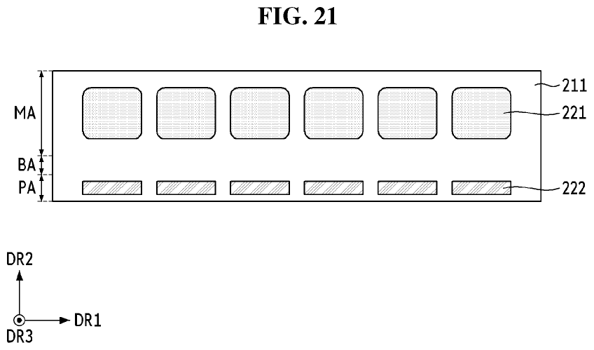

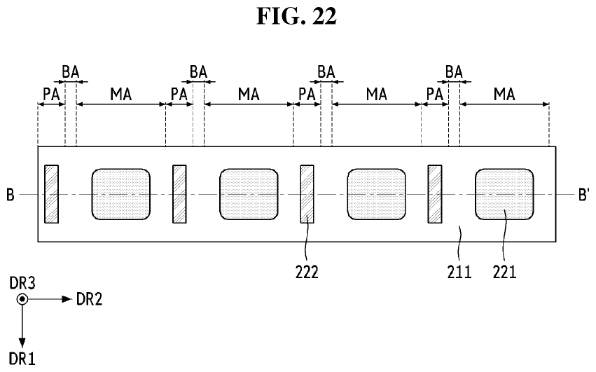

FIG. 20 is a plan view of an embodiment, illustrating a first adhesive film, a first structural layer, and a second structural layer. FIG. 21 is a plan view of an embodiment, illustrating a first adhesive film, a first structural layer, and a second structural layer. FIG. 22 is a plan view of an embodiment, illustrating a first adhesive film, a first structural layer, and a second structural layer.

Referring to FIG. 20, in an embodiment of a method for manufacturing a protective film, the second structural layer 222 may be formed in a straight line in the pad region PA of the first adhesive film 211 of FIG. 18. Referring to FIG. 21, a plurality of second structural layers 222 may be formed to be spaced apart from each other in the pad region PA of the first adhesive film 211 of FIG. 18. Referring to FIG. 22, a plurality of second structural layers 222 may be formed to be spaced apart from each other in the pad region PA of the first adhesive film 211 of FIG. 16. The second structural layer 222 may be located to overlap the first structural layer 221 in the second direction DR2. When the first structural layer 221 and the second structural layer 222 are located on the first adhesive film 211 as shown in FIGS. 20 to 22, the protective film 200 in which the first structural layer 221 and the second structural layer 222 are arranged in the same layer may be manufactured, similar to the protective film 200 according to the embodiment of FIG. 6 or the protective film 200 according to the embodiment of FIG. 10.

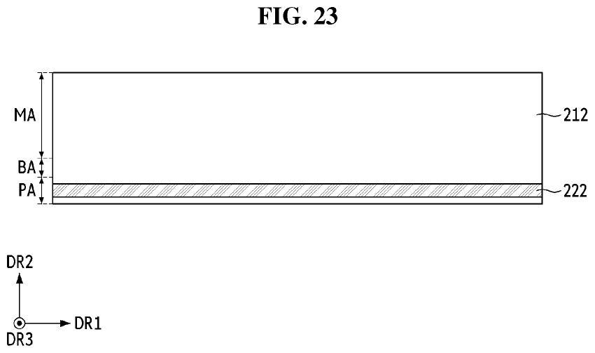

FIG. 23 is a plan view of an embodiment, illustrating a second adhesive film and a second structural layer.

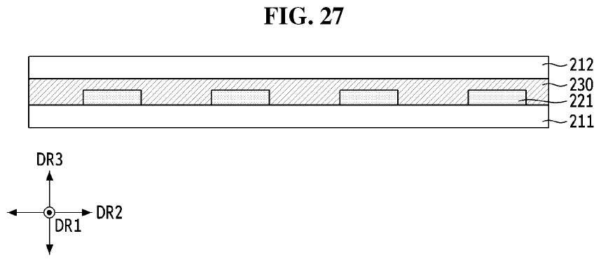

In order to manufacture an embodiment of the protective film 200 in which the first structural layer 221 and the second structural layer 222 are located in different layers, e.g., the protective film 200 according to the embodiment of FIG. 7 or the protective film 200 according to the embodiment of FIG. 9, the second structural layer 222 may be prepared by being formed on a second adhesive film 212, as shown in FIG. 23. The surface of the first adhesive film 211 on which the first structural layer 221 is located as shown in FIG. 18, and the surface of the second adhesive film 212 on which the second structural layer 222 is located may be arranged to face each other. A resin layer 230 (see FIG. 27) may be interposed between the first adhesive film 211 and the second adhesive film 212 that face each other.

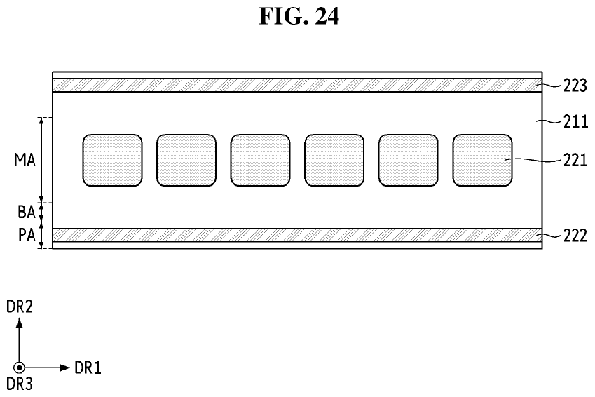

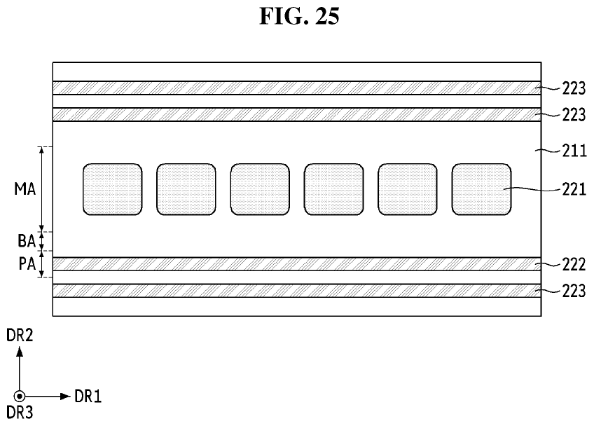

FIG. 24 is a plan view of an embodiment, illustrating a first adhesive film, a first structural layer, and a second structural layer. FIG. 25 is a plan view of an embodiment, illustrating a first adhesive film, a first structural layer, and a second structural layer.

Referring to FIG. 24, in an embodiment of a method for manufacturing a protective film, a third structural layer 223 including a polymer may be further located in a region symmetrical to the second structural layer 222 with respect to the first structural layer 221. Referring to FIG. 25, a third structural layer may be further located in a region symmetrical to the second structural layer 222 with respect to the first structural layer. The third structural layer 223 may be further located at a distance from the second structural layer 222, and another third structural layer 223 may be further located in a region symmetrical to the aforementioned third structural layer 223 with respect to the first structural layer 221. The plurality of third structural layers 223 and the second structural layer 222 may include the same or different polymers.

As shown in FIG. 20, when the first adhesive film 211 on which the first structural layer 221 and the second structural layer 222 are located is used in a roll-to-roll process, a weight imbalance may occur since the second structural layer 222 is located on one side. Accordingly, by further arranging or providing the third structural layer 223 in a region symmetrical to the second structural layer 222, a balance may be achieved when the first adhesive film 211 is applied to the roll-to-roll process.

Hereinafter, for simplicity of description, a process will be described based on a case in which the first adhesive film 211 is arranged in a rectangular planar shape having short sides in the first direction DR1 and long sides in the second direction DR2 intersecting the first direction DR1, as shown in FIG. 16. However, the present disclosure is not limited thereto, and the protective film 200 may be manufactured by the process to be described below using the first adhesive film 211 shown in FIGS. 13, 14, and 17 to 25.

Subsequently, the resin layer 230 is formed on the first adhesive film 211 on which the plurality of first structural layers 221 are formed (process S200). The resin layer 230 may be formed using the material used for the first resin layer 231 and the second resin layer 232 described above, and a process used for forming the resin layer 230 is not limited.

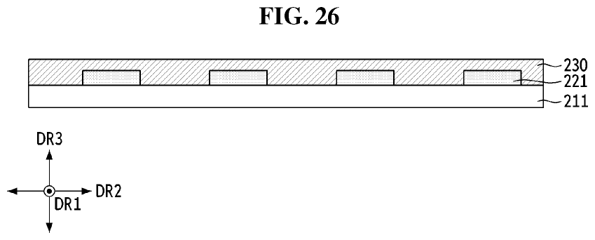

FIG. 26 is a cross-sectional view of an embodiment, illustrating the first adhesive film, the first structural layer, and the resin layer in process S200 of FIG. 15.

Referring to FIG. 26, in an embodiment of a method for manufacturing a protective film, the resin layer 230 may be formed to cover the plurality of first structural layers 221 arranged on the first adhesive film 211.

Subsequently, the second adhesive film 212 is formed on the resin layer 230 (process S300). The second adhesive film 212 may be formed using the material exemplified above for the first adhesive layer 210, and a process used for forming the second adhesive film 212 is not limited.

Process S200 of forming the resin layer 230 and process S300 of forming the second adhesive film 212 may be performed simultaneously using at least one method selected from gap coating, roll-to-roll, doctor blade, and offset coating.

FIG. 27 is a cross-sectional view of an embodiment, illustrating the first adhesive film, the first structural layer, the resin layer, and the second adhesive film in processes S200 and S300 of FIG. 15.

Referring to FIG. 27, in an embodiment of a method for manufacturing a protective film, the resin layer 230 may be formed in a way such that a uniform distance is maintained between the first adhesive film 211 and the second adhesive film 212. In an embodiment, for example, when forming the second adhesive film 212, the distance between the first adhesive film 211 and the second adhesive film 212 may be kept uniform by applying a uniform pressure.

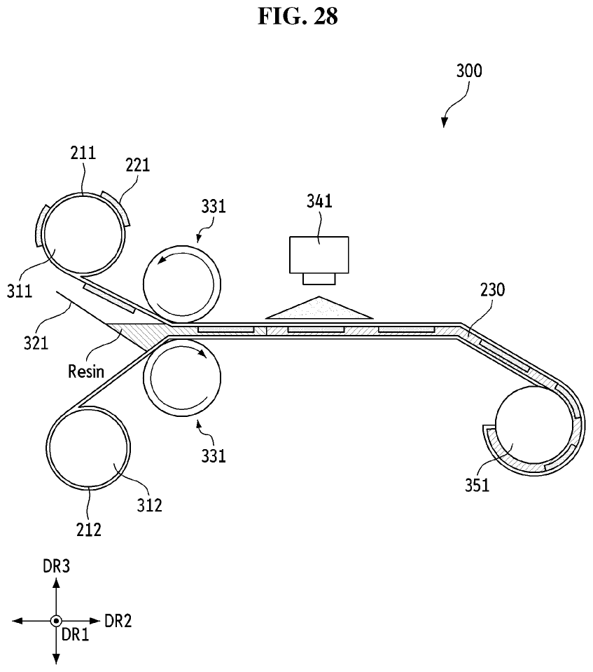

Process S200 of forming the resin layer 230 and process S300 of forming the second adhesive film 212 may be performed simultaneously using at least one method selected from gap coating, roll-to-roll, doctor blade, and offset coating. FIG. 28 illustrates a case in which a gap coating method is used.

FIG. 28 is a diagram showing an embodiment of a manufacturing apparatus for manufacturing the first adhesive film, the first structural layer, the resin layer, and the second adhesive film in processes S200 and S300 of FIG. 15.

Referring to FIG. 28, an embodiment of a manufacturing apparatus 300 of the display device may include a first supply unit 311, a second supply unit 312, a first resin bath 321, first gap rollers 331, a first light irradiation unit 341, and a first recovery unit 351.

The first supply unit 311 may provide the first adhesive film 211 on which the first structural layer 221 is formed. In this case, the first supply unit 311 may include a roller on which the first adhesive film 211 with the first structural layer 221 formed thereon is wound. The first supply unit 311 may further include a motor that is connected to the roller and moves the first adhesive film 211, with the first structural layer 221 formed thereon, by rotating the roller.

A film for protecting the first structural layer 221 may be further wound on the roller on which the first adhesive film 211, with the first structural layer 221 formed thereon, is wound. A recovery unit for removing the film may further be included.

The second supply unit 312 may provide the second adhesive film 212. In this case, the second supply unit 312 may include a roller on which the second adhesive film 212 is wound. The second supply unit 312 may further include a motor that is connected to the roller and moves the second adhesive film 212 by rotating the roller.

The first resin bath 321 may provide a space for accommodating a resin. The first resin bath 321 may be located between the first supply unit 311 and the second supply unit 312, and may provide a resin between the first adhesive film 211 provided from the first supply unit 311 and the second adhesive film 212 provided from the second supply unit 312. The resin may have a viscosity of about 10,000 centipoise (cps) or less. The resin may have a modulus (e.g., Young's modulus) of about 100 megapascals (MPa) or more after curing.

The first gap rollers 331 may be located at one end of the first resin bath 321 and may apply a uniform pressure to the top and bottom of the first adhesive film 211 and the second adhesive film 212 while the resin is supplied from the first resin bath 321 between the first adhesive film 211 provided from the first supply unit 311 and the second adhesive film 212 provided from the second supply unit 312, thereby making the thickness uniform. In this case, when the thickness between the first gap rollers 331 is set to be the same as the thickness of the first structural layer 221 and/or the second structural layer 222, the protective film 200 in which the first structural layer 221 is in contact with the first adhesive layer 210 and the first bonding layer 241, as shown in FIGS. 11 and 12, may be manufactured. The first gap rollers 331 may include a plurality of motors that rotate in opposite directions. The first gap rollers 331 may determine the thickness between the first adhesive film 211 and the second adhesive film 212 based on a set thickness value. As pressure is increased on the first adhesive film 211, the second adhesive film 212, and the resin passing between the first gap rollers 331, undesired air bubbles are removed, and a film having a uniform distance between the first adhesive film 211 and the second adhesive film 212 may be manufactured.

Subsequently, the resin layer 230 is cured (process S400). The curing of the resin layer 230 may be performed by thermal curing or ultraviolet curing. The curing method may be determined depending on the properties of the resin.

The first light irradiation unit 341 may irradiate the resin interposed between the first adhesive film 211 and the second adhesive film 212 with light, thereby curing the resin into the resin layer 230. The first light irradiation unit 341 may radiate ultraviolet light. The light may be radiated in the form of a line beam extending in the second direction DR2. However, the present disclosure is not limited thereto, and the light may be radiated in the form of a surface beam that extends in the second direction DR2 and also has a selected width in the first direction DR1.

The intensity and/or exposure time of the ultraviolet light radiated onto the resin layer overlapping the pad region PA may be greater than the intensity and/or exposure time of the ultraviolet light radiated onto the resin layer overlapping the main region MA. Since the main region MA includes the first structural layer 221, the modulus (e.g., Young's modulus) of the main region MA may be greater than that of the pad region PA. In order to support the display panel 100 in the pad region PA, the resin layer 230 in the pad region PA may be further cured.

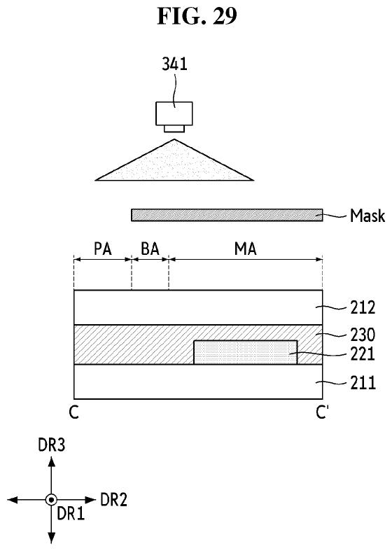

FIG. 29 is a diagram illustrating the photocuring of the first adhesive film, the first structural layer, the resin layer, and the second adhesive film in process S400 of FIG. 15.

Referring to FIG. 29, the method may further include a process of forming a mask on the main region MA, or on the main region MA and the bending region BA to expose the pad region PA, and then curing the resin layer 230 using the first light irradiation unit 341. The power and/or intensity of the first light irradiation unit 341 may be set higher when radiating light to the resin layer 230 in the pad region PA than when radiating light to the entire resin layer 230.

The curing rate of the resin layer 230 in the pad region PA may be higher than that of the resin layer 230 in the main region MA. The elastic modulus of the resin layer 230 in the pad region PA may be greater than that of the resin layer 230 in the main region MA.

In an embodiment where the second structural layer 222 is included in the pad region PA, a process of further curing the resin layer 230 in the pad region PA may be omitted.

The first recovery unit 351 may recover the first adhesive film 211, the first structural layer 221, the resin layer 230, and the second adhesive film 212 that have been cured and formed into a film by the first light irradiation unit 341. In this case, the first recovery unit 351 may include a roller capable of winding the first adhesive film 211, the first structural layer 221, the resin layer 230, and the second adhesive film 212.

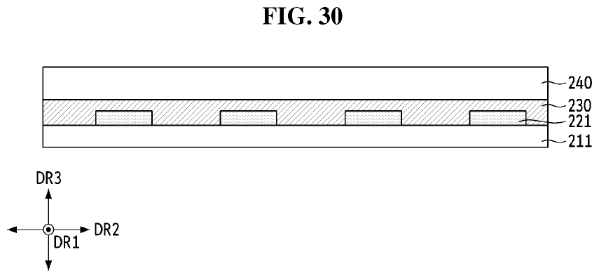

Subsequently, a bonding layer 240 (see FIG. 30) is formed on the resin layer 230, which is exposed by removing the first adhesive film 211 or the second adhesive film 212 (process S500). When the second adhesive film 212 is removed, the first adhesive film 211 becomes the first adhesive layer 210, and the protective film 200 in which the first structural layer 221 is in contact with the first adhesive layer 210, as in the embodiments of FIGS. 5 to 7, may be manufactured. When the first adhesive film 211 is removed, the second adhesive film 212 becomes the first adhesive layer 210, and the protective film 200 in which the first structural layer 221 is in contact with the bonding layer 240, as in the embodiments of FIGS. 8 to 10, may be manufactured. A process used for forming the bonding layer 240 is not limited.

FIG. 30 is a cross-sectional view of an embodiment, illustrating the first adhesive film, the first structural layer, the resin layer, and the bonding layer in process S500 of FIG. 15.

FIG. 30 illustrates an embodiment in which the bonding layer 240 is formed after removing the second adhesive film 212, but the present disclosure is not limited thereto. In an embodiment, for example, where the bonding layer 240 is formed after removing the first adhesive film 211, the first structural layer 221 may be in contact with the bonding layer 240.

Subsequently, a third adhesive film 213 is formed on the bonding layer 240 (process S600). The third adhesive film 213 may be formed using the material exemplified above for the first adhesive layer 210, and a process used for forming the third adhesive film 213 is not limited.

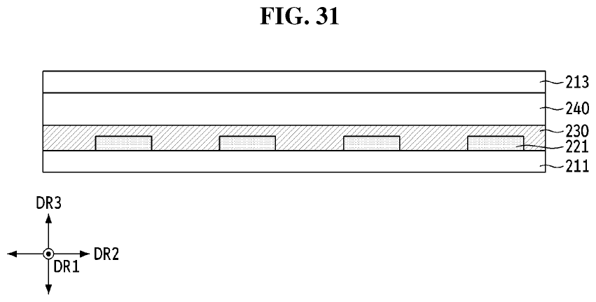

FIG. 31 is a cross-sectional view of an embodiment, illustrating the first adhesive film, the first structural layer, the resin layer, the bonding layer, and the third adhesive film in process S600 of FIG. 15.

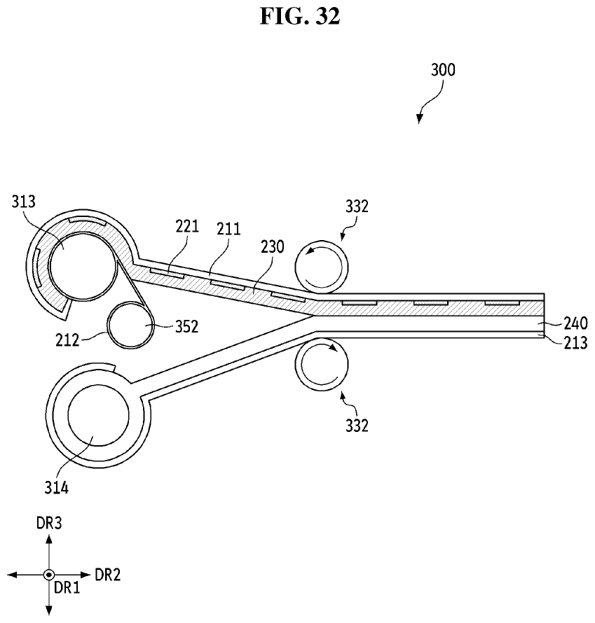

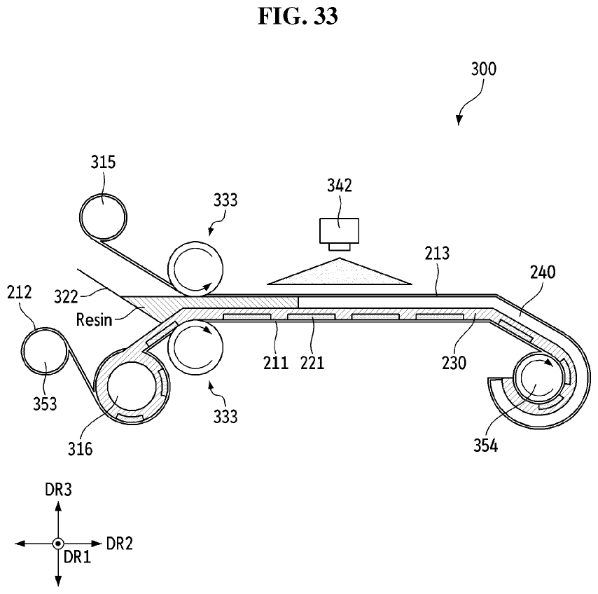

Process S500 of forming the bonding layer 240 and process S600 of forming the third adhesive film 213 may be performed simultaneously using at least one method selected from gap coating, roll-to-roll, doctor blade, and offset coating. FIGS. 32 and 33 illustrate examples in which the process is carried out using a gap coating method. FIGS. 32 and 33 illustrate different embodiments of the gap coating method.

FIG. 32 is a diagram illustrating an embodiment of a manufacturing apparatus for manufacturing the first adhesive film, the first structural layer, the resin layer, the bonding layer, and the third adhesive film in processes S500 and S600 of FIG. 15.

Referring to FIG. 32, an embodiment of the manufacturing apparatus 300 of the display device may include a third supply unit 313, a fourth supply unit 314, a second recovery unit 352, and second gap rollers 332.

The third supply unit 313 may provide the first adhesive film 211, the first structural layer 221, the resin layer 230, and the second adhesive film 212 recovered by the first recovery unit 351. The third supply unit 313 may be connected to or identical to the first recovery unit 351. Alternatively, after the film is recovered from the first recovery unit 351, it may be supplied to the third supply unit 313. The third supply unit 313 may include a roller on which the first adhesive film 211, the first structural layer 221, the resin layer 230, and the second adhesive film 212 are wound. In addition, the third supply unit 313 may include a motor that is connected to the roller and moves the first adhesive film 211, the first structural layer 221, the resin layer 230, and the second adhesive film 212 by rotating the roller.

The second recovery unit 352 may recover the first adhesive film 211 or the second adhesive film 212 from the third supply unit 313. In this case, the second recovery unit 352 may include a roller capable of winding the first adhesive film 211 or the second adhesive film 212. Although FIG. 32 illustrates that the second adhesive film 212 is recovered, the present disclosure is not limited thereto.

The fourth supply unit 314 may provide the third adhesive film 213 on which the bonding layer 240 is formed. In this case, the fourth supply unit 314 may include a roller on which the third adhesive film 213 with the bonding layer 240 formed thereon is wound. In addition, the fourth supply unit 314 may include a motor that is connected to the roller and moves the third adhesive film 213, with the bonding layer 240 formed thereon, by rotating the roller.

The second gap rollers 332 may be located at a selected distance from the third supply unit 313 and the fourth supply unit 314 and may bond the first adhesive film 211, the first structural layer 221, and the resin layer 230 provided from the third supply unit 313 to the third adhesive film 213, with the bonding layer 240 formed thereon, which is provided from the fourth supply unit 314. The second gap rollers 332 may include a plurality of motors that rotate in opposite directions. A uniform pressure may be applied to the top and bottom of the first adhesive film 211 and the third adhesive film 213 to make the thickness uniform. The thickness between the first adhesive film 211 and the third adhesive film 213 may be determined based on a thickness value set in the second gap rollers 332. As pressure is increased on the first adhesive film 211 and the third adhesive film 213 passing between the second gap rollers 332, undesired air bubbles are removed, and a film having a uniform distance between the first adhesive film 211 and the third adhesive film 213 may be manufactured.

FIG. 33 is a diagram illustrating an embodiment of a manufacturing apparatus for manufacturing the first adhesive film, the first structural layer, the resin layer, the bonding layer, and the third adhesive film in processes S500 and S600 of FIG. 15.

Referring to FIG. 33, an embodiment of the manufacturing apparatus 300 of the display device may include a fifth supply unit 315, a sixth supply unit 316, a third recovery unit 353, a fourth recovery unit 354, third gap rollers 333, and a second light irradiation unit 342.

The fifth supply unit 315 may provide the third adhesive film 213. In this case, the fifth supply unit 315 may include a roller on which the third adhesive film 213 is wound. The fifth supply unit 315 may further include a motor that is connected to the roller and moves the third adhesive film 213 by rotating the roller.

The sixth supply unit 316 may provide the first adhesive film 211, the first structural layer 221, the resin layer 230, and the second adhesive film 212 recovered by the first recovery unit 351. The sixth supply unit 316 may be connected to or identical to the first recovery unit 351. Alternatively, after the film is recovered from the first recovery unit 351, it may be supplied to the sixth supply unit 316. The sixth supply unit 316 may include a roller on which the first adhesive film 211, the first structural layer 221, the resin layer 230, and the second adhesive film 212 are wound. In addition, the sixth supply unit 316 may include a motor that is connected to the roller and moves the first adhesive film 211, the first structural layer 221, the resin layer 230, and the second adhesive film 212 by rotating the roller.

The third recovery unit 353 may recover the first adhesive film 211 or the second adhesive film 212 from the sixth supply unit 316. In this case, the third recovery unit 353 may include a roller capable of winding the first adhesive film 211 or the second adhesive film 212. Although FIG. 33 illustrates an embodiment where the second adhesive film 212 is recovered, but the present disclosure is not limited thereto.

A second resin bath 322 may provide a space for accommodating a resin. The second resin bath 322 may be located between the fifth supply unit 315 and the sixth supply unit 316, and may provide a resin between the third adhesive film 213 provided from the fifth supply unit 315 and the first adhesive film 211, the first structural layer 221, and the resin layer 230 provided from the sixth supply unit 316.

The third gap rollers 333 may be located at one end of the second resin bath 322, and may apply a uniform pressure to the top and bottom of the first adhesive film 211 and the third adhesive film 213 while the resin is supplied from the second resin bath 322 between the third adhesive film 213 supplied from the fifth supply unit 315 and the first adhesive film 211 supplied from the sixth supply unit 316, thereby making the thickness uniform. The third gap rollers 333 may include a plurality of motors that rotate in opposite directions. The third gap rollers 333 may determine the thickness between the first adhesive film 211 and the third adhesive film 213 based on a set thickness value. As pressure is increased on the first adhesive film 211, the third adhesive film 213, and the resin passing between the third gap rollers 333, undesired air bubbles are removed, and a film having a uniform distance between the first adhesive film 211 and the third adhesive film 213 may be manufactured.

The third recovery unit 353 may recover the first adhesive film 211 or the second adhesive film 212 from the sixth supply unit 316. In this case, the third recovery unit 353 may include a roller capable of winding the first adhesive film 211 or the second adhesive film 212. Although FIG. 33 illustrates an embodiment where the second adhesive film 212 is recovered, the present disclosure is not limited thereto.

The second light irradiation unit 342 may irradiate the resin interposed between the third adhesive film 213 and the resin layer 230 with light, thereby curing it into the bonding layer 240. The second light irradiation unit 342 may radiate ultraviolet light. The light may be radiated in the form of a line beam extending in the second direction DR2. However, the present disclosure is not limited thereto, and the light may be radiated in the form of a surface beam that extends in the second direction DR2 and also has a selected width in the first direction DR1.

The fourth recovery unit 354 may recover the first adhesive film 211, the first structural layer 221, the resin layer 230, the bonding layer 240, and the third adhesive film 213 that have been cured and formed into a film by the second light irradiation unit 342. In this case, the fourth recovery unit 354 may include a roller capable of winding the first adhesive film 211, the first structural layer 221, the resin layer 230, the bonding layer 240, and the third adhesive film 213.

Subsequently, the bending region BA is formed by removing a portion of each of the resin layer 230, the bonding layer 240, and the third adhesive film 213 (process S700). The method for removing a portion of the resin layer 230, the bonding layer 240, and the third adhesive film 213 may be performed by laser cutting, but is not limited thereto.

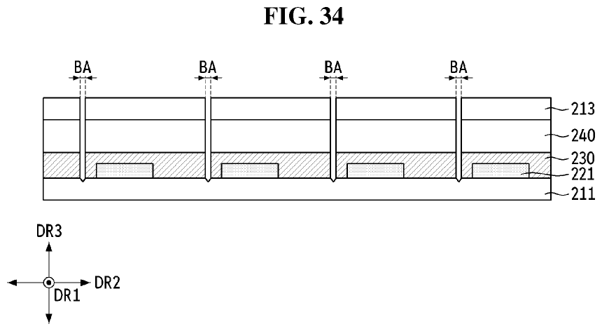

FIG. 34 is a cross-sectional view of an embodiment, illustrating the first adhesive film, the first structural layer, the resin layer, the bonding layer, and the third adhesive film in process S700 of FIG. 15.

Referring to FIG. 34, the bending region BA is formed by removing portions of the resin layer 230, the bonding layer 240, and the third adhesive film 213. By removing the resin layer 230, the bonding layer 240, and the third adhesive film 213 in the bending region BA, the bending of the protective film 200 attached to the display panel 100 may be facilitated.

By removing the bending region BA of the resin layer 230, the resin layer 230 corresponding to the main region MA may be referred to as the first resin layer 231, and the resin layer 230 corresponding to the pad region PA may be referred to as the second resin layer 232.

By removing the bending region BA of the bonding layer 240, the bonding layer 240 corresponding to the main region MA may be referred to as the first bonding layer 241, and the bonding layer 240 corresponding to the pad region PA may be referred to as the second bonding layer 242.

Subsequently, the film is cut into cell units, each including the main region MA and the pad region PA, which are spaced apart with the bending region BA interposed between the main region MA and the pad region PA (process S800). The method for cutting into cell units may be performed by laser cutting, but is not limited thereto.

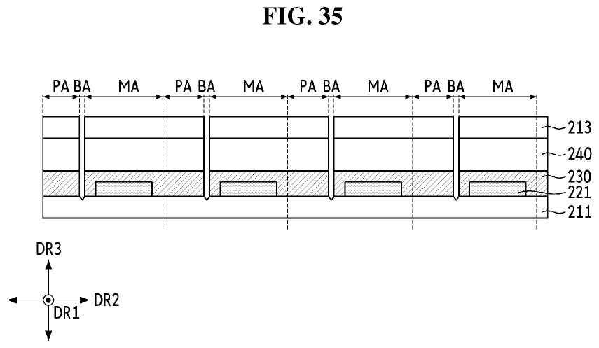

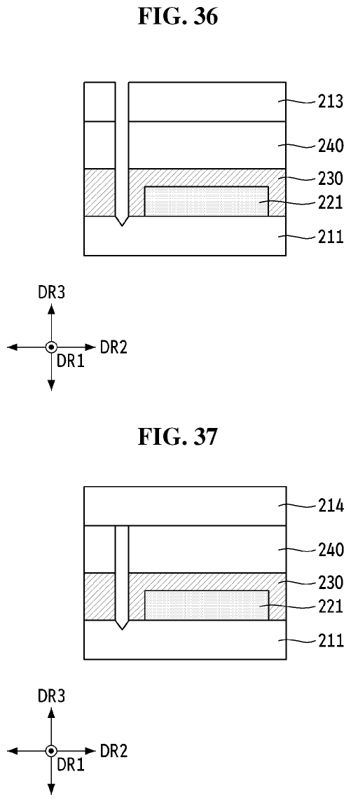

FIG. 35 is a cross-sectional view of an embodiment, illustrating the first adhesive film, the first structural layer, the resin layer, the bonding layer, and the third adhesive film in process S800 of FIG. 15. FIG. 36 is a cross-sectional view of one embodiment, illustrating the protective film manufactured after being cut into cell units in step S800 of FIG. 15.

Referring to FIG. 35, cutting lines are illustrated for cutting into cell units, each including the main region MA, the bending region BA, and the pad region PA. The protective film 200, after being cut into cell units, may be illustrated as shown in FIG. 36. As shown in FIG. 36, the third adhesive film 213 may become the second adhesive layer 250. The third adhesive film 213 from which the bending region BA has been removed may facilitate the bending of the display panel 100 in the bending region BA.

Process S800 of cutting into cell units may be performed before process S700. Alternatively, processes S700 and S800 may be performed simultaneously. When processes S700 and S800 are performed simultaneously, in the bending region BA, only the third adhesive film 213, the bonding layer 240, and the resin layer 230 may be removed such that the first adhesive film 211 is not removed. Between the main region MA of an arbitrary first cell and the pad region PA of a second cell, which corresponds to a boundary between the first and second cells, the third adhesive film 213, the bonding layer 240, the resin layer 230, and the first adhesive film 211 may be fully cut. The first structural layer 221 overlaps the main region MA. In an embodiment where the protective film 200 further includes the second structural layer 222, the second structural layer 222 overlaps the pad region PA.

Subsequently, a process of removing the third adhesive film 213 and forming a fourth adhesive film 214 on the bonding layer 240 may further be included. The release force of the third adhesive film 213 may be less than that of the first adhesive film 211. Accordingly, the third adhesive film 213 may be easily removed from the bonding layer 240. The third adhesive film 213 may correspond to the second adhesive layer 250. After removing the third adhesive film 213, the protective film 200 may be attached to the bottom of the display panel 100.

FIG. 37 is a cross-sectional view of an embodiment, illustrating the protective film manufactured after being cut into cell units.

Referring to FIG. 37, the fourth adhesive film 214 may correspond to the second adhesive layer 250. The fourth adhesive film 214 including the bending region BA may effectively prevent damage to the protective film 200 during the movement of the protective film 200 before the protective film 200 is attached to the display panel 100. After removing the fourth adhesive film 214, the protective film 200 may be attached to the bottom of the display panel 100.

Conventionally, the process for manufacturing the protective film 200 in which the first structural layer 221 is included in the main region MA involved five or more punching processes and ten or more lamination processes. The conventional process had problems in that it was complicated, resulting in a high process cost, and the large number of lamination processes caused tolerances in the film.

In embodiments of the present disclosure, the process may be simplified to a single punching process and a single lamination step, thereby reducing the process cost. In such embodiments, by reducing the number of lamination processes during the process, the tolerances that may occur in the protective film 200 may be minimized, thereby improving reliability.

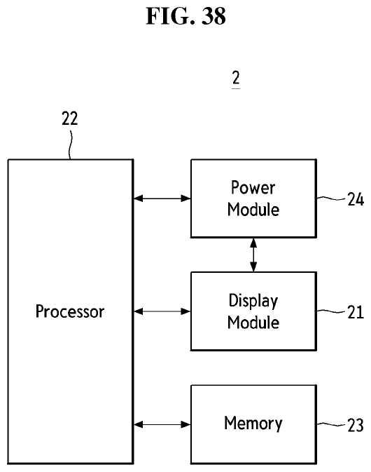

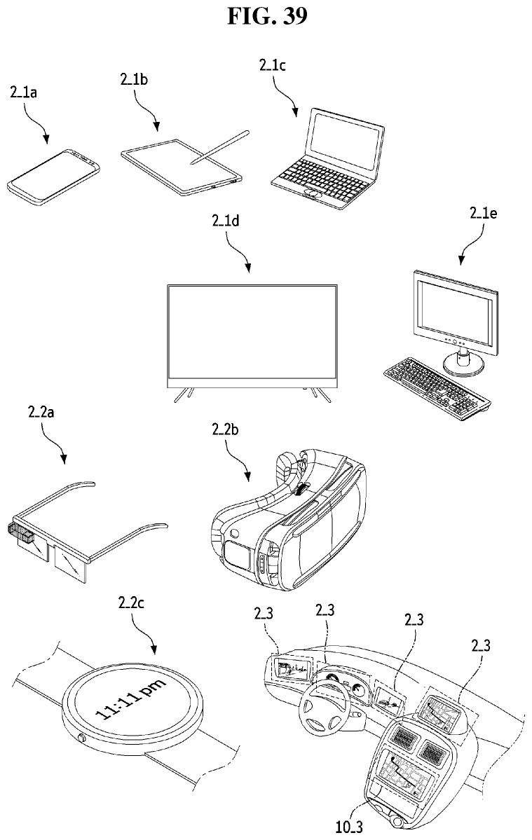

FIG. 38 is a block diagram of an electronic device according to an embodiment.

Referring to FIG. 38, an electronic device 2 according to an embodiment may include a display module 21, a processor 22, a memory 23, and a power module 24.

The processor 22 may include at least one selected from a central processing unit (CPU), an application processor (AP), a graphic processing unit (GPU), a communication processor (CP), an image signal processor (ISP), or a controller.

The memory 23 may store data information used for the operation of the processor 22 or the display module 21. When the processor 22 executes an application stored in the memory 23, an image data signal and/or an input control signal is transmitted to the display module 21, and the display module 21 may process the received signal and output image information through a display screen.

The power module 24 may include a power supply module, such as a power adapter or a battery device, and a power conversion module that converts the power supplied by the power supply module to generate the power used for the operation of the electronic device 2.

At least one of the components of the electronic device 2 described above may be included in the display device 1 according to the embodiments described above. Further, some of individual modules functionally included in one module may be included in the display device 1 and some others may be provided separately from the display device 1. In an embodiment, for example, the display device 1 may include the display module 21, and the processor 22, the memory 23, and the power module 24 may be provided in the form of other devices in the electronic device 2 other than the display device 1.

FIG. 39 is schematic views of electronic devices according to various embodiments.

Referring to FIG. 39, various electronic devices 2 to which the display device according to embodiments is applied may include not only an image display electronic device such as a smartphone 2_1a, a tablet PC 2_1b, a laptop computer 2_1c, a TV 2_1d, and a desk monitor 2_1e, but also a wearable electronic device including a display module, such as smart glasses 2_2a, a head mounted display 2_2b, a smart watch 2_2c, or the like, a vehicle electronic device 2_3 including a display module, such as an instrument panel of a vehicle, a center fascia, a center information display (CID) provided on a dashboard, or a room mirror display, and the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A protective film comprising:
a first adhesive layer comprising a main region and a pad region spaced apart from each other with a bending region interposed between the main region and the pad region;
a first structural layer disposed on the main region of the first adhesive layer and comprising glass or metal;
a first resin layer disposed on the main region of the first adhesive layer;
a second resin layer disposed on the pad region of the first adhesive layer;
a first bonding layer disposed on the first resin layer;
a second bonding layer disposed on the second resin layer; and
a second adhesive layer disposed on the first bonding layer and the second bonding layer and overlapping the main region, the pad region, and the bending region,
wherein the first resin layer and the second resin layer comprise a same material as each other.

2. The protective film of claim 1, wherein a difference between a thickness of the first resin layer and a thickness of the second resin layer is equal to or less than about 1 μm.

3. The protective film of claim 1, wherein a difference between a distance from the first adhesive layer to the second adhesive layer in the main region and a distance from the first adhesive layer to the second adhesive layer in the pad region is equal to or less than about 1 μm.

4. The protective film of claim 1, wherein the glass comprises ultra thin glass (UTG) or hybrid thin glass.

5. The protective film of claim 1, wherein the first structural layer is in contact with the first adhesive layer.

6. The protective film of claim 1, wherein the first structural layer is in contact with the first bonding layer.

7. The protective film of claim 1, wherein a modulus of the first resin layer is less than a modulus of the second resin layer.

8. The protective film of claim 1, further comprising:
a second structural layer disposed on the pad region of the first adhesive layer and including a polymer.

9. The protective film of claim 8, wherein a modulus of the second structural layer is equal to or greater than about 2.0 GPa.

10. The protective film of claim 8, wherein the second structural layer is in contact with the first adhesive layer.

11. The protective film of claim 8, wherein the second structural layer is in contact with the first bonding layer.

12. The protective film of claim 1, wherein the first structural layer has a pattern.

13. A method for manufacturing a protective film, the method comprising:
forming a plurality of first structural layers to be spaced apart from each other on a first adhesive film, wherein the plurality of first structural layers comprises glass or metal;
forming a resin layer on the first adhesive film on which the plurality of first structural layers are formed;
forming a second adhesive film on the resin layer;
curing the resin layer;
forming a bonding layer on the resin layer exposed by removing the first adhesive film or the second adhesive film;
forming a third adhesive film on the bonding layer;
manufacturing a protective film by removing a portion of each of the resin layer, the bonding layer, and the third adhesive film to form a bending region; and
cutting the protective film into cell units comprising a main region and a pad region spaced apart from each other with the bending region interposed between the main region and the pad region,
wherein the first structural layer overlaps the main region.

14. The method of claim 13, further comprising removing the third adhesive film and forming a fourth adhesive film on the bonding layer.

15. The method of claim 13, wherein the forming the resin layer and the forming the second adhesive film are performed simultaneously using at least one method selected from gap coating, roll-to-roll, doctor blade, and offset coating.

16. The method of claim 13, wherein the forming the bonding layer and the forming the third adhesive film are performed simultaneously using at least one method selected from gap coating, roll-to-roll, doctor blade, and offset coating.

17. The method of claim 13, wherein in the curing the resin layer, ultraviolet light is radiated to the resin layer, and an intensity and/or exposure time of the ultraviolet light radiated onto the resin layer overlapping the pad region is greater than an intensity and/or exposure time of the ultraviolet light radiated onto the resin layer overlapping the main region.

18. The method of claim 13, further comprising forming:
forming a second structural layer on the pad region of the first adhesive film, wherein the second structural layer comprises a polymer.

19. The method of claim 18, further comprising forming:
forming a third structural layer on the first adhesive film in a region symmetrical to the second structural layer with respect to the first structural layer formed on the first adhesive film, wherein the third structural layer comprises a polymer.

20. An electronic device comprising:
a display device which displays an image;
a processor which transmits an image data signal to the display device,
wherein the display device comprises:
a display panel; and
a protective film disposed on the display panel,
wherein the protective film comprises:
a first adhesive layer comprising a main region and a pad region spaced apart from each other with a bending region interposed between the main region and the pad region;
a first structural layer disposed on the main region of the first adhesive layer and comprising glass or metal;
a first resin layer disposed on the main region of the first adhesive layer;
a second resin layer disposed on the pad region of the first adhesive layer;
a first bonding layer disposed on the first resin layer and overlapping the main region under the display panel; and
a second bonding layer disposed on the second resin layer and overlapping the pad region under the display panel,
wherein the first resin layer and the second resin layer comprise a same material as each other.
